(19) United States
(12) Patent Application Publication
(10) Pub. No.: US 2020/0304023 A1
(43) Pub. Date: Sep. 24, 2020

(54) SWITCHING POWER CONVERTER SYSTEM

(71) Applicant: HIENSCH INNOVATIONS B.V., Velp (NL)

(72) Inventor: Henk-Albert HIENSCH, Velp (NL)

(21) Appl. No.: 16/089,074

(22) PCT Filed: Mar. 29, 2016
(86) PCT No.: PCT/NL2016/050215

§ 371 Date: Sep. 27, 2018

(51) Int. Cl. H02M 3/07; H03F 3/217; H02M 3/158

(52) U.S. Cl. CPC H02M 3/073; H03F 3/2178; H02M 2001/0048; H02M 2003/077; H02M 3/158

(57) ABSTRACT

A switching power converter system includes a crosswise switching charge pump setting implemented with at least two auxiliary units and at least one interlace unit, in which the crosswise switching charge pump setting may generate a summated positive as well as negative switched voltage alternately with respect to a reference voltage. The crosswise switching charge pump setting includes a configuration of an interlace unit intermediately coupled in cascade with an auxiliary unit being pre-coupled and an auxiliary unit being post-coupled to form a H8H topology for transferring and summating electrical charge, in which the interlace unit of the H8H topology is operable to couple in response to at least one pulse modulated control signal the auxiliary unit being pre-coupled with the auxiliary unit being post-coupled repetitively in accordance with a high operational state and a low operational state of the interlace unit.

### FIELD OF THE INVENTION

The invention relates to a switching power converter system, and more specifically to a crosswise switching charge pump setting capable of transferring and summating electrical charge for generating a summated positive as well as negative switched voltage alternately with respect to a reference voltage and in particular applicable for generating a switching high voltage signal being pulse-width-modulated (PWM) in response to a control signal.

### DESCRIPTION OF RELATED AND PRIOR ART

In general the semiconductor industry has made great progress in the last decennia's, however despite the great progress, it is still not possible to provide for example a half bridge switching power setting comprising only two series connected and counter phase driven semiconductors (MOSFET, IGBT, BJT) being operable to generate a switching output voltage of several kilovolts in combination with a high operational switching frequency as well as fast transition times.

In addition, it is to be noted that with an increase of switching output voltage at an output of the half bridge switching power setting (not shown) comprising only two semiconductors connected in series, a cross-current flow through the semiconductors during each transition will increase as well due to an output capacitance resided in each constituted semiconductor with a consequence of a more or less exponential increase of switching losses in the half bridge switching power setting with a linear increase of switching output voltage.

In general in order to implement a half bridge or full bridge switching power setting operable to generate a switching output voltage of several kilovolts, several semiconductors may be connected in series splitting the switching output voltage into an applicable blocking voltage being equally divided across each semiconductor and consequently splitting the total loss in the constituted semiconductors as well, as will be well understood by those skilled in the art. In addition, it is to be noted that with the series connection of several semiconductors as described above the output capacitance resided in each constituted semiconductor will be series connected as well achieving by means of the series connection a decreased overall output capacitance obtaining reduced switching losses as well as reduced transition times. However tolerance of the constituted components may introduce divergent switching behaviour for each semiconductor taken alone resulting in reduced reliability as well as disturbed behaviour.

In order to overcome these deficiencies to a greater or lesser extent a network of diodes and capacitors may be implemented in a manner as shown for example in reference document “Voltage Sag Restorer with Diode-Clamped Multilevel Bridge” published in the Asian Power Electronics Journal, Vol. 5 No. 1, August 2011, in which a fixed blocking voltage for each semiconductor may be set. However due to a complex configuration of components and therefore hard to implement with respect to high frequency (HF) properties as well as an inevitable large amount of stray inductance due to a series connection of several semiconductors in combination with the additional deficiencies as described above, the prior art concept will have limitations in order to achieve a well-designed switching power converter setting.

A switching charge pump setting of the prior art as shown in FIG. 1 implemented with a plurality of switching elements and capacitive elements may generate a summated positive switching output voltage Uout provided at terminal TO with respect to a reference voltage Uref, in which each of the respective capacitive elements C1, C2 and C3 may be charged during operation to a voltage level equal to a voltage between a supply voltage UinH and the reference voltage Uref to generate a peak-peak value of the summated positive switching output voltage Uout with respect to the reference voltage equal to a summation of each voltage level provided across the respective capacitive elements C1, C2 and C3. In operation the switching charge pump setting as shown in FIG. 1 may employ in response to a control signal two operational states during a switching period being associated with an operational switching frequency of the switching charge pump setting. During a first operational state the switching charge pump setting may provide a switched voltage Uout equal to the reference voltage Uref, in which the switching elements SL1, SL2, SL3, Q1 and Q2 are conductive in combination with the switching elements SH1, SH2 and SH3 being non-conductive, and in which the capacitive elements C2 and C3 may be charged to a voltage level equal to a voltage between the supply voltage UinH and the reference voltage Uref. During a second operational state the switching charge pump setting may provide a summated positive switched output voltage Uout with respect to the reference voltage Uref equal to the summation of each voltage provided across the respective capacitive elements C1, C2 and C3, in which the switching elements SH1, SH2 and SH3 are conductive in combination with switching elements SL1, SL2, SL3, Q1 and Q2 being non-conductive. The switching charge pump setting as shown in the FIG. 1 exhibits a non-balanced configuration generating a non-balanced switching output voltage Uout with respect to the reference voltage Uref and therefore additional means may be implemented such as for example a DC bias voltage or a DC blocking capacitor to provide a balanced switching output voltage with respect to a reference voltage, in which the additional means may affect the signal characteristics of the balanced switching output voltage negatively.

The switching charge pump setting of the prior art as shown in FIG. 1 may be implemented in an opposite variant thereof as well (not shown) for generating a summated negative switching output voltage with respect to a reference voltage as will be well understood by those skilled in the art.

A combination of the switching charge pump setting as shown in FIG. 1 and the opposite variant thereof may result in a switching charge pump setting as shown in FIG. 2 for generating a summated positive as well as negative switching output voltage Uout provided at terminal TO with respect to a reference voltage Uref, in which each of the respective capacitive elements C1, C2, C3 and C4 may be charged during operation to a voltage level equal to a voltage between a supply voltage UinH and the reference voltage Uref to generate a peak-peak value of the summated positive and negative switching output voltage Uout equal to a summation of each voltage level provided across the respective capacitive elements C1, C2, C3 and C4. In operation the switching charge pump setting as shown in FIG. 2 may employ in response to a control signal two operational states during a switching period being associated with an operational switching frequency of the switching charge pump setting. During a first operational state the switching charge pump setting may provide a summated positive switched output voltage Uout with respect to the reference voltage Uref equal to the summation of each voltage provided across the capacitive elements C1 and C3, in which the switching elements SH1, SH2, SH3, SH4, Q1 and Q3 are conductive in combination with the switching elements SL1, SL2, SL3, SL4 and Q2 being non-conductive, and in which capacitive element C2 may be charged to a voltage level equal to a voltage across capacitive element C1 and capacitive element C4 may be charged to a voltage level equal to a voltage across capacitive element C3. During a second operational state the switching charge pump setting may provide a summated negative switched output voltage Uout with respect to the reference voltage Uref equal to the summation of each voltage provided across the capacitive elements C2 and C4, in which the switching elements SL1, SL2, SL3, SL4 and Q2 are conductive in combination with switching elements SH1, SH2, SH3, SH4, Q1 and Q3 being non-conductive, and in which capacitive element C3 may be charged to a voltage level equal to a voltage across capacitive element C2. Consequently the switching charge pump setting as shown in FIG. 2 may generate the summated positive as well as negative switching output voltage Uout with respect to the reference voltage Uref, in which the use of additional DC bias means as well as DC blocking capacitor means may be omitted. However it is to be noted that the switching charge pump setting as shown in FIG. 1 as well as the opposite variant thereof exhibits a non-balanced circuit configuration resulting in case the respective switching elements are implemented with for example semiconductors (MOSFET, IGBT, BJT, DIODE) in a varying output capacitance being non-balanced along a rising edge transition with respect to the varying output capacitance along a falling edge transition of a summated switching output voltage and therefore resulting in a deviation between a rising edge transition time and a falling edge transition time of the summated switching output voltage. Consequently the deviation in transition times will affect performance negatively in a time related setting employing for example a summated switching output voltage being pulse width modulated (PWM). Subsequently the combination of the switching charge pump setting as shown in FIG. 1 and the opposite variant thereof aiming at a balanced circuit configuration of a switching charge pump setting as shown in FIG. 2 and therefore aiming at a balanced output capacitance will result in a generation of a summated positive as well as negative switching output voltage Uout with respect to a reference voltage Uref comprising residual non-balanced signal properties in a time related as well as a voltage related domain and consequently reduced performance. As described above U.S. Pat. No. 3,748,492 discloses such prior art switching charge pump settings in accordance with both the FIGS. 1 and 2.

A switching power converter as shown in FIG. 3 comprises a plurality of full bridge power stages connected in cascade, in which the switching power converter may generate a summated positive as well as negative switching output voltage Uout provided at terminal TO with respect to a reference voltage Uref equal to a summation of each voltage provided across the respective voltage sources V1, V2 and V3. The switching power converter as shown in FIG. 3 exhibits a balanced circuit configuration, in which the balanced circuit configuration may result in case the respective switching elements are implemented with for example semiconductors (MOSFET, IGBT, BJT) in a varying output capacitance being balanced along a rising edge transition with respect to the varying output capacitance along a falling edge transition of the summated positive as well as negative switching output voltage Uout and therefore may result in a rising edge transition time being identical to a falling edge transition time of the summated positive as well as switching output voltage. In operation the switching power converter as shown in FIG. 3 may employ in response to a control signal two operational states during a switching period being associated with an operational switching frequency of the switching power converter. During a first operational state the switching power converter may provide a summated positive switched output voltage Uout with respect to the reference voltage Uref equal to the summation of each voltage provided across the respective voltage sources V1, V2 and V3, in which the switching elements SL1, QH1, SL2, QH2, SL3 and QH3 are conductive in combination with the switching elements SH1, QL1, SH2, SL2, SH3 and SL3 being non-conductive. During a second operational state the switching power converter may provide a summated negative switched output voltage Uout with respect to the reference voltage Uref equal to the summation of each voltage provided across the respective voltage sources V1, V2 and V3, in which the switching elements SH1, QL1, SH2, SL2, SH3 and SL3 are conductive in combination with switching elements SL1, QH1, SL2, QH2, SL3 and QH3 being non-conductive. U.S. Pat. No. 6,160,445 discloses such a prior art switching power converter. In contrast to the switching charge pump settings as shown in the FIGS. 1 and 2 the switching power converter generally requires an independent voltage source V1, V2 and V3 for each full bridge switching power stage as shown in FIG. 3 being galvanically isolated with respect to the reference voltage Uref to operate properly due to a lack of a charge pump capability as described in accordance with the FIGS. 1 and 2. Subsequently the implementation of a voltage source being galvanically isolated with respect to the reference voltage Uref may yield a capacitive coupling between an isolated barrier (not shown) of the voltage source being galvanically isolated and a reference node (not shown) providing the reference voltage Uref, in which an implementation of a transformer (not shown) comprising a parasitic interwinding capacitance and therefore the capacitive coupling between a first and second winding for providing the isolated barrier is commonly used. Consequently due to a capacitance of each capacitive coupling between the respective voltage sources and the reference node accumulated forming an accumulated capacitive load the performance of the switching power converter may be severely degraded particularly in a high voltage setting employing a high operational switching frequency and aiming at fast transition times during switching, in which the accumulated capacitive load of the switching power converter may result in a high increase of switching losses and electromagnetic interference (EMI) during operation.

### SUMMARY OF THE INVENTION

According to the above stated deficiencies that exist with prior art configurations, the objective of the present invention is to provide a switching power converter system capable of generating a high resolution well-balanced high voltage pulse-width-modulated (PWM) signal switched at a high operational switching frequency with fast balanced transition times in combination with a very energy efficient concept by means of a H8H topology.

In accordance with the present invention the switching power converter system includes a charge pump component responsive to at least one pulse modulated control signal, in which the charge pump component comprises a crosswise switching charge pump setting implemented with at least two auxiliary units and at least one interlace unit. The crosswise switching charge pump setting comprises a configuration of an interlace unit intermediately coupled in cascade with an auxiliary unit being pre-coupled and an auxiliary unit being post-coupled to form a H8H topology, in which the interlace unit is one of the at least one interlace unit, and in which the auxiliary unit being pre-coupled and the auxiliary unit being post-coupled are two of the at least two auxiliary units. The interlace unit of the H8H topology is operable to couple in response to one or more of the at least one pulse modulated control signal the auxiliary unit being pre-coupled with the auxiliary unit being post-coupled repetitively in accordance with a high operational state and a low operational state of the interlace unit. The switching power converter system is characterised in that each of the at least two auxiliary units comprises a high side capacitance section and a low side capacitance section coupled in series as well as a high side terminal, a common side terminal and a low side terminal, in which the high side capacitance section is coupled between the high side terminal and the common side terminal, and in which the low side capacitance section is coupled between the common side terminal and the low side terminal. The interlace unit of the H8H topology is operable to couple during the high operational state the high side terminal of the auxiliary unit being pre-coupled with the common side terminal of the auxiliary unit being post-coupled and the common side terminal of the auxiliary unit being pre-coupled with the low side terminal of the auxiliary unit being post-coupled, and the interlace unit is operable to couple during the low operational state the common side terminal of the auxiliary unit being pre-coupled with the high side terminal of the auxiliary unit being post-coupled and the low side terminal of the auxiliary unit being pre-coupled with the common side terminal of the auxiliary unit being post-coupled.

In accordance with the present invention a crosswise switching charge pump setting implemented with at least two auxiliary units and at least one interlace unit may be configured to form one or more H8H topologies, in which an interlace unit being one of the at least one interlace unit is alternately coupled in cascade with an auxiliary unit being one of the at least two auxiliary units or a cluster comprising a parallel coupling of two or more of the at least two auxiliary units. In addition the crosswise switching charge pump setting may be started as well as ended with an auxiliary unit being one of the at least two auxiliary units, a cluster comprising the parallel coupling of two or more of the at least two auxiliary units or an interlink unit.

In accordance with the present invention a crosswise switching charge pump setting is implemented with at least two auxiliary units and at least one interlace unit, in which in particular a common side terminal of each of the at least two auxiliary units may be capable to provide a reference voltage, to provide the means for a coupling with for example a load, to provide the means for a coupling of the switching power converter system or a combination thereof, and in which an interlace unit being one of the at least one interlace unit includes an interlink terminal in particular capable to provide a positive switched voltage as well as negative switched voltage with respect to a reference voltage, to provide the means for a coupling with for example a load, to provide the means for a coupling of the switching power converter system or a combination thereof. In addition in accordance with the present invention the crosswise switching charge pump setting may comprise an interlink unit, in which the interlink unit may include an interlink terminal in particular capable to provide a positive as well as negative switched voltage with respect to a reference voltage, to provide the means for a coupling with for example a load, to provide the means for a coupling of the switching power converter system or a combination thereof.

In accordance with a further aspect of the present invention a crosswise switching charge pump setting implemented with at least two auxiliary units and at least one interlace unit may comprise the parallel coupling of two or more of the at least two auxiliary units to form a cluster, in which the cluster comprising the parallel coupling of two or more of the at least two auxiliary units may further comprise low pass filter means, resonant filter means, voltage regulator means, protection means, inrush current limiter means, current monitoring means or a combination thereof.

According to the further aspect of the present invention a cluster comprising the parallel coupling of two or more of the at least two auxiliary units may further comprise low pass filter means subdivided in high side low pass filter means and low side low pass filter means, in which two auxiliary units included in the parallel coupling of the cluster may comprise a coupling between the high side terminals interposed by the high side low pass filter means, a coupling of the common side terminals and a coupling between the low side terminals interposed by the low side low pass filter means to set an attenuated frequency range between the high side terminals being interposed as well as to set an attenuated frequency range between the low side terminals being interposed. Subsequently a crosswise switching charge pump setting implemented with at least two auxiliary units and at least one interlace unit is configured to form a H8H topology of an interlace unit intermediately coupled in cascade with an auxiliary unit being pre-coupled and an auxiliary unit being post-coupled, in which the auxiliary unit being pre-coupled in cascade with the interlace unit is included in a parallel coupling of two or more of the at least two auxiliary units to form a cluster being pre-coupled to the interlace unit, and in which the auxiliary unit being post-coupled in cascade with the interlace unit is included in a parallel coupling of two or more of the at least two auxiliary units to form a cluster being post-coupled to the interlace unit. Consequently in case the cluster being pre-coupled as well as the cluster being post-coupled further includes high side low pass filter means and low side low pass filter means in a manner as described above, than the configuration of the H8H topology supplemented with snubber means may result in highly improved characteristic switching properties in a high frequency (HF) range of the interlace unit providing fast well-balanced transition times during switching, an absence of any ringing, and reduced electromagnetic interference (EMI). In addition the cluster being pre-coupled as well as the cluster being post-coupled further including high side low pass filter means and low side low pass filter means in a manner as described above may provide the means for increasing a physical distance between two of the at least one interlace unit as well as between one of the at least one interlace unit and an interlink unit without compromising the characteristic switching properties, in which an increase of the physical distance may provide the means for passive cooling as well as for an extended capacitance of one or more of the at least two auxiliary units.

In addition according to the further aspect of the present invention a cluster comprising a parallel coupling of two or more of the at least two auxiliary units may further comprise voltage regulator means interposed in a parallel coupling between two auxiliary units of the cluster, in which the voltage regulator means may comprise a linear regulator setting, a switched-mode power supply (SMPS) setting or a combination thereof operable to regulate, to restore, to adapt or a combination thereof for setting an adjusted voltage at an output of the voltage regulator means.

In accordance with the present invention a crosswise switching charge pump setting configured to form a H8H topology comprising a first circuit setting of an interlace unit being preferred as will be described in detail hereinafter allows for a downright stable and a highly HF optimized concept capable of generating a high voltage pulse modulated signal in a kilovolt range, an output capacitor less (OCL) setting, a high operational switching frequency up to and above 5 MHz, fast well-balanced transition times, a very energy efficient concept, four quadrant operation characteristic for driving a complex load, a single-bit setting for generating a two level summated positive switched voltage as well as negative switched voltage, a multi-bit setting for generating a multi-level positive switched voltage as well as a multi-level negative switched voltage, in which the multi-bit setting providing gradient capabilities may include a level of zero volt. Needless to say, that although the crosswise switching charge pump setting is in particular suitable for high voltage operation, low voltage operation in general may be suitable to a same extent.

It is to be noted, that the switching power converter system in the scope of the present invention is capable of operating at various voltage levels in conjunction with various power levels, with various pulse modulator topology settings, with various pulse modulation techniques, at various performance levels, in which the switching power converter system may employ one or more crosswise switching charge pump settings implemented in a single configuration, a differential configuration, a three-phase configuration or a poly-phase configuration.

Applications for the switching power converter system are numerous and may include Class-D amplification, Class-G amplification or a combination thereof to provide Class-H amplification, High Voltage power DAC for a direct drive of a capacitive load of an electrostatic loudspeaker, an electric motor, a magnetic resonance imaging system (MRI), an electron microscope, scientific applications in general, grid-tied inverter, generator-tied inverter, AC/AC converter, DC/AC converter, AC/DC converter and DC/DC converter.

### SHORT DESCRIPTION OF DRAWINGS

The present invention will be discussed in detail hereinafter exhibiting several exemplary embodiments with reference to the attached drawings that are intended to illustrate the present invention but not to limit its scope which is defined by the annexed claims and its equivalent embodiment, in which

FIG. 1 illustrates a schematic diagram showing a switching charge pump setting of the prior art capable of generating a summated positive switching output voltage,

FIG. 2 illustrates a schematic diagram showing a switching charge pump setting of the prior art capable of generating a summated positive as well as negative switching output voltage,

FIG. 3 illustrates a schematic diagram showing a switching power converter of the prior art capable of generating a summated positive as well as negative switching output voltage,

FIG. 4 illustrates a basic conceptual block diagram of a switching power converter system,

FIG. 5 illustrates a configuration of a H8H topology comprising a first circuit setting of an interlace unit being preferred,

FIG. 5A illustrates the configuration of the H8H topology comprising the first circuit setting being the preferred constituted with actively driven semiconductors,

FIG. 5B illustrates the configuration of the H8H topology comprising the first circuit setting being the preferred constituted with passively and actively driven semiconductors,

FIG. 5C illustrates the configuration of the H8H topology comprising a variation of the circuit diagram as shown in FIG. 5 for adjusting means,

FIG. 5D illustrates the configuration of the H8H topology comprising a variation of the circuit diagram as shown in FIG. 5 for adjusting means,

FIG. 6 illustrates the configuration of the H8H topology comprising a second circuit setting of the interlace unit being an alternative,

FIG. 6A illustrates the configuration of the H8H topology comprising the second circuit setting being the alternative constituted with actively driven semiconductors,

FIG. 6B illustrates the configuration of the H8H topology comprising the second circuit setting being the alternative constituted with passively and actively driven semiconductors,

FIG. 7 illustrates a circuit diagram an interlink unit coupled in cascade with an auxiliary unit being pre-coupled,

FIG. 8 illustrates a circuit diagram of a crosswise switching charge pump setting configured with three H8H topologies overlapping one another,

FIG. 8A illustrates in accordance with the circuit diagram as shown in FIG. 8 the manner of the high side and the low side capacitance sections being coupled during the high operational state of each of the interlace units,

FIG. 8B illustrates in accordance with the circuit diagram as shown in FIG. 8 the manner of the high side and the low side capacitance sections being coupled during the low operational state of each of the interlace units,

FIG. 9 illustrates a resulting voltage generated arbitrarily during a time frame being one of fourteen time frames,

FIG. 10 illustrates a circuit diagram of a crosswise switching charge pump setting implemented with configuration of a H8H topology, an interlink unit an two clusters in accordance with a further aspect of the present invention,

FIG. 11 illustrates a circuit diagram of an extended auxiliary unit and an extended switching unit coupled in cascade with a crosswise switching charge pump setting configured with two H8H topologies overlapping one another,

FIG. 12 illustrates a circuit diagram of a crosswise switching charge pump setting supplemented with galvanic isolated power supply means as well as gate drive means,

FIG. 13 illustrates a circuit diagram of a crosswise switching charge pump setting constituted in part with integrated circuits and characterised as a ripple through converter asynchronously controlled.

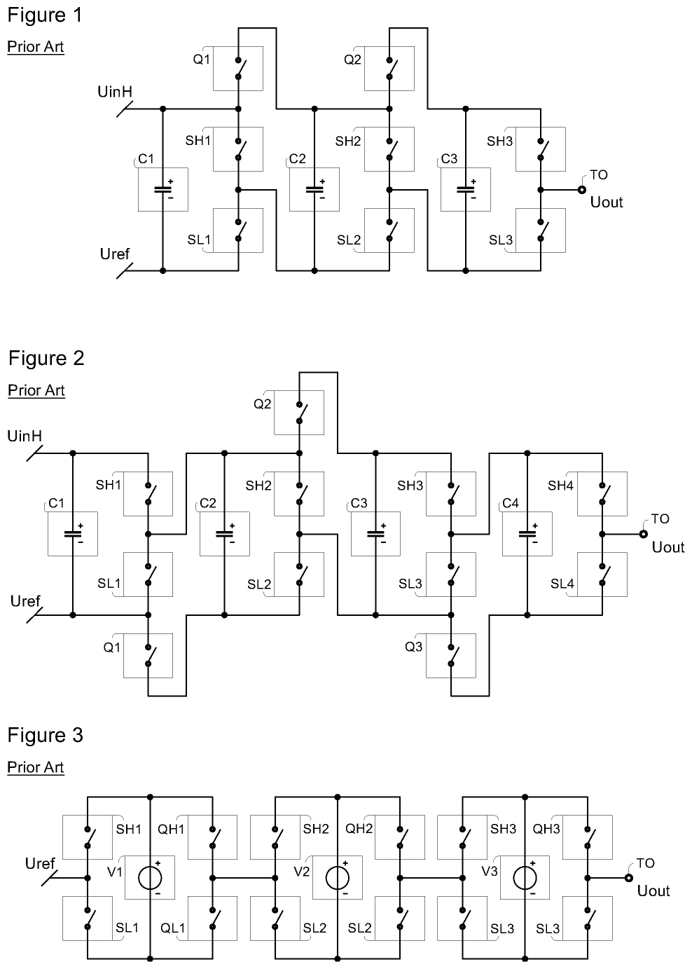

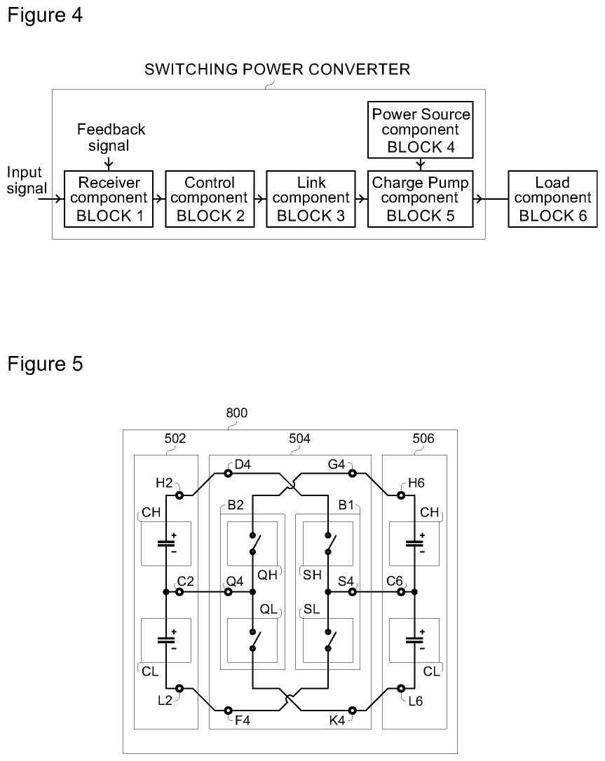

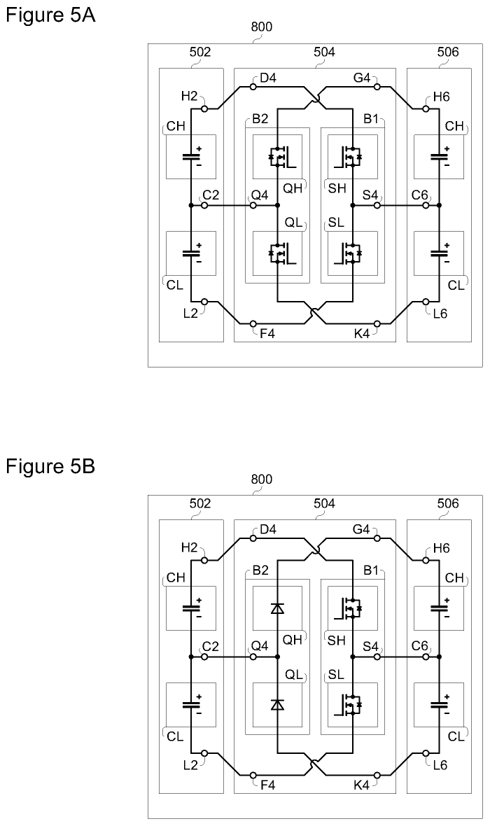

### DESCRIPTION OF EXEMPLARY EMBODIMENTS

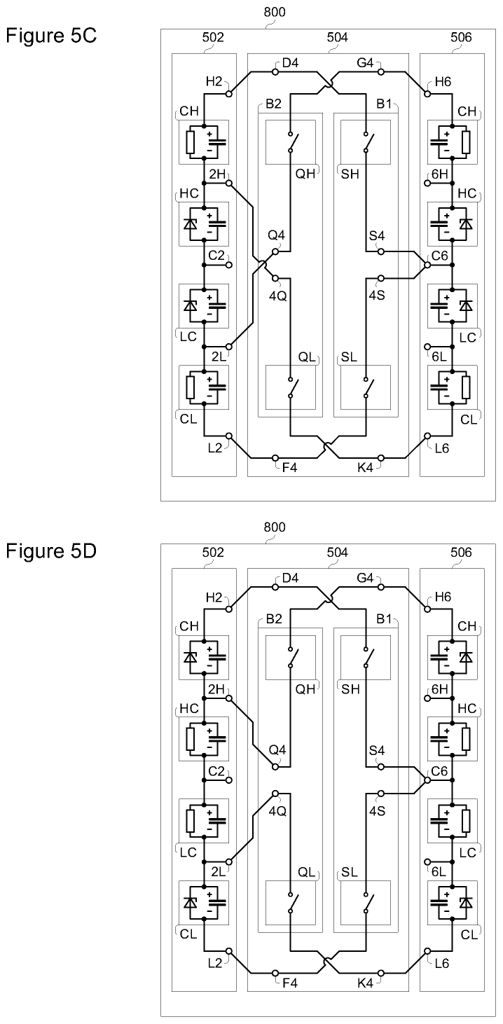

In accordance with the present invention a basic conceptual block diagram of a switching power converter system as shown in FIG. 4 may comprise a receiving component BLOCK 1, a control component BLOCK 2, a link component BLOCK 3, a power source component BLOCK 4 and a charge pump component BLOCK 5, in which the basic conceptual block diagram of the switching power converter system is supplemented with a load component BLOCK 6.

As illustrated in FIG. 4 BLOCK 1 a receiving component may comprise signal input means at an input of the switching power converter system, in which the signal input means may be configured to receive one or more input signals such as for example an analogue formatted input signal, a digital formatted input signal, a pulse modulated input signal in general, a pulse modulated control signal being one of at least one pulse modulated control signal generated for the charge pump component as shown in FIG. 4 BLOCK 5, a pulse width modulated input signal, a feedback signal for adjusting characteristic signal properties of the switching power converter system in response to the feedback signal, a feed forward signal for adjusting characteristic signal properties of the switching power converter system in response to the feed forward signal, a clock signal for synchronisation means, a carrier frequency for pulse modulation means or a combination thereof. Needless to say that an implementation of the signal input means may be balanced, unbalanced, optical, wireless or a combination thereof.

As illustrated in FIG. 4 BLOCK 2, a control component may be configured to generate at least one pulse modulated control signal for the charge pump component as shown in FIG. 4 BLOCK 5, in which a pulse modulated control signal being one of the at least one pulse modulated control signal may comprise a pulse width modulated signal (PWM), a pulse density modulated signal (PDM) or a combination thereof. A pulse modulated control signal being one of the at least one pulse modulated control signal may be configured to control for example an actively driven semiconductor or an integrated switching power module included in a crosswise switching charge pump setting part of the charge pump component as shown in FIG. 4 BLOCK 5. A pulse modulated control signal being one of the at least one pulse modulated control signal may be generated in response to the one or more input signals of the signal input means part of the receiving component as shown in FIG. 4 BLOCK 1, in response to internal circuitry of the control component or a combination thereof, in which for example a pulse modulated control signal being one of the at least one pulse modulated control signal is responsive to the internal circuitry of the control component in order to maintain proper operation of a crosswise switching charge pump setting part of the charge pump component and more specific to maintain a charged status of at least two auxiliary units included in the crosswise switching charge pump setting during an absence of the one or more input signals of the signal input means. It is to be emphasised that a pulse modulated control signal being one of the at least one pulse modulated control signal may be emanated from the receiving component as shown in FIG. 4 BLOCK 1, a pulse modulated control signal being one of the at least one pulse modulated control signal may be emanated from the control component as shown in FIG. 4 BLOCK 2 or a combination thereof, in which the control component may be omitted in whole or in part.

In accordance with protection means and supporting means the control component may comprise for example a limiter function obviating possible over-modulation of a pulse modulated control signal being one of the at least one pulse modulated control signal, in which the limiter function may maintain a minimum and a maximum duty cycle of the pulse modulated control signal in order to be limited within a minimum pulse width as being set, and according to signal support means the control component may comprise a delay timing control, in which the delay timing control is configured to adapt the pulse modulated control signal by adding a delay time also called dead time to delay a rising edge transition or a falling edge transition of the pulse modulated control signal resulting in a delay of a transition from a non-conductive state into a conductive state of for example an actively driven semiconductor being responsive to the pulse modulated control signal. The delay timing control is commonly used to prevent cross conduction during a voltage transition of for example two counter phase and actively driven semiconductors series connected in a half bridge setting as will be well understood by those skilled in the art.

In accordance with pulse modulator means the control component may comprise a pulse modulation setting being well-known or more application specific employing for example pulse width modulation, pulse density modulation or a combination thereof, in which the pulse modulator setting may be analogue based, digital based or a combination thereof such as for example a self-oscillating pulse modulator, a delta-sigma modulator, field-programmable gate array (FPGA) in conjunction with a pulse modulator embedded in software or an audio related TAS5558 HD PWM processor from Texas Instruments supplemented with a sample rate converter (SRC) and a digital signal processor (DSP).

In addition according to the pulse modulator setting the control component may be configured to generate the at least one pulse modulated control signal by means of for example the pulse modulator setting being single-bit configured in an AD modulation mode for driving a crosswise switching charge pump setting part of the charge pump component as shown in FIG. 4 BLOCK 5, a pulse width modulator setting being dual-bit configured in a BD modulation mode for driving two crosswise switching charge pump settings differentially implemented or a pulse modulator setting being multi-bit configured for driving one or more crosswise switching charge pump settings to provide gradient capabilities, in which two or more of the at least one pulse modulated control signal independently of one another may be generated with different switching periods in a time domain as well as in a frequency domain by means of the pulse modulator setting being multi-bit configured.

A link component as shown in FIG. 4 BLOCK 3 may comprise a transmission link for conducting a pulse modulated control signal being one of the at least one pulse modulated control signal exhibiting a key part with respect to the characteristic switching properties of a crosswise switching charge pump setting part of the charge pump component as shown in FIG. 4 BLOCK 5. Subsequently for a proper operation of the crosswise switching charge pump setting it may be vital to implement the transmission link comprising a galvanically isolated barrier to obtain floating properties of for example an actively driven semiconductor being responsive to the pulse modulated control signal and being one of the respective actively driven semiconductors included in the crosswise switching charge pump setting, in which each of the respective actively driven semiconductors may be responsive to a pulse modulated control signal being conducted by means of using a transmission link comprising a galvanically isolated barrier to obtain the proper operation. In addition a transmission link comprising a galvanically isolated barrier may be constituted in whole or in part with an optical signal conductor to obtain the galvanically isolated barrier, in which another part of the transmission link comprising the galvanically isolated barrier may be constituted with an electrical signal conductor coupled to the optical signal conductor. The electrical signal conductor may be implemented with for example an embedded track on a printed circuit board (PCB), a coaxial conductor or a shielded twisted pair conductor and the like, in which the electrical signal conductor may comprise a characteristic impedance as constant as possible along a physical path length of the electrical signal conductor, and in which a resistive element may be coupled to an input of the electrical signal conductor equal to the characteristic impedance without the use of any termination means coupled to an output of the electrical signal conductor other than for example a capacitive input impedance at an input of a fast switching current source coupled to the output.

It is to be noted, that an implementation of a transmission link comprising a galvanically isolated barrier is not limited to an optical signal conductor to obtain the galvanically isolated barrier by means of an optically coupled signal conductor and may include transformer means to obtain a galvanically isolated barrier by means of a magnetically coupled signal conductor.

An objective of a transmission link is to maintain integrity of the characteristic signal properties of a pulse modulated control signal being one of the at least one pulse modulated control signal.

A first arrangement according to the objective of the transmission link relates to the pulse modulated control signal converted into two triggering pulse signals comprising trigger pulses, in which a trigger pulse being one of the trigger pulses may exhibit a maximum pulse duration of two times a minimum pulse duration of the pulse modulated control signal. For example a trigger pulse of a first triggering pulse signal is derived from each rising edge transition of the pulse modulated control signal and a trigger pulse of a second triggering pulse signal is derived from each falling edge transition of the pulse modulated control signal, in which a switching frequency of the first triggering pulse signal as well as the second triggering pulse signal will be halved with respect to an operational switching frequency of the pulse modulated control signal. In a case the pulse modulated control signal is pulse width modulated the first arrangement may result in a low frequency signal in the range of for example 20 Hz to 70 KHz such as an audio formatted signal being mainly encompassed in a phase related condition between the first triggering pulse signal and second triggering pulse signal rather than a time related condition in accordance with the pulse modulated control signal, in which the first triggering pulse signal as well as the second triggering pulse signal exhibit nearly constant characteristic signal properties in a high frequency range starting at for example 100 KHz providing a nearly constant amplitude correlation between the harmonics. It is to be noted that a pulse modulated control signal may be converted in one triggering pulse signal as well, the one triggering pulse signal comprising trigger pulses, in which a trigger pulse being one of the trigger pulses may exhibit a maximum pulse duration equal to a minimum pulse duration of the pulse modulated control signal. For example a trigger pulse of the one triggering pulse signal may be derived from each rising edge transition of the pulse modulated control signal and a trigger pulse of the one triggering pulse signal may be derived from each falling edge transition of the pulse modulated control signal, in which a trigger pulse derived from each rising edge transition exhibits a pulse duration twice as long as a trigger pulse derived from each falling edge transition for distinguishing a rising edge transition from a falling edge transition to maintain the correct signal level information in case the one triggering pulse signal is converted back into the pulse modulated control signal. Alternatively rather than a trigger pulse exhibiting the pulse duration twice as long two or more trigger pulses may be generated in response to a rising edge transition of the pulse modulated control signal for distinguishing a trigger pulse being single in response to a falling edge transition of the pulse modulated control signal provided that a maximum duration of two or more trigger pulses may be equal to the minimum pulse duration of the pulse modulated control signal.

A second arrangement according to the objective of the transmission link relates to a transmission link comprising a galvanic isolated barrier as described above, in which the transmission link comprising the galvanic isolated barrier may be implemented with two signal conductors. In accordance with the first arrangement a first signal conductor may conduct a first triggering pulse signal and a second signal conductor may conduct a second triggering pulse signal, in which the first triggering pulse signal and the second triggering pulse signal are derived from a pulse modulated control signal being one of the at least one pulse modulated control signal. In addition the first signal conductor as well as the second signal conductor may be constituted with an electrical signal conductor coupled to an optical signal conductor, in which the first signal conductor and the second signal conductor may be substantially identical to obtain an equal delay time for the first triggering pulse signal and the second triggering pulse signal during conduction.

On a basis of the first signal conductor being substantially identical to the second signal conductor an implementation of the optical signal conductor of the first signal conductor will be described hereinafter, in which the implementation of the optical signal conductor of the second signal conductor will be described accordingly. Subsequently the optical signal conductor of the first signal conductor may be implemented with an optical transmitter as well as an optical receiver, in which an output of the optical transmitter coupled to an input of the optical signal conductor may be constituted with an infra-red light emitting diode (IR LED) comprising a high radiant intensity rating and fast switching times. In addition an input of the optical transmitter may be coupled to an output of a fast switching current source and the input of the fast switching current source may be coupled to the output of the electrical signal conductor, in which during a conducting state the infra-red light emitting diode may be driven with a current pulse generated by the fast switching current source in response to the first triggering pulse signal for converting the first triggering pulse signal having electrical properties into the first triggering pulse signal having optical properties, in which a time duration of the conducting state may be equal to a time duration of a trigger pulse as being set for the first triggering pulse signal.

An optical receiver having an input coupled to an output of the optical signal conductor may be constituted with a photodiode comprising a fast response time such as for example a silicon PIN photodiode for converting the first triggering pulse signal having optical properties presented at the input of the optical receiver back into the first triggering pulse signal having electrical properties provided at an output of the optical receiver, in which the photodiode may employ a photoconductive mode (PC) in conjunction with a relative high reverse voltage resulting during the conducting state in response of the first triggering pulse signal in a current through the photodiode being in a near saturated or saturated condition, and in which the output of the optical receiver may provide the output of the first signal conductor.

A third arrangement according to the objective of the transmission link relates to the implementation of the optical signal conductor of the first signal conductor as will be described hereinafter, in which the implementation of the optical signal conductor of the second signal conductor will be described accordingly. Subsequently the optical signal conductor of the first signal conductor having the input coupled to the output of the optical transmitter and the output of the optical signal conductor coupled to the input of the optical receiver, in which the optical signal conductor exhibits a light guide implemented with a straight hollow tube comprising a cylindrical outer surface and a cylindrical inner surface such as for example a straight hollow tube made of glass or acrylic comprising the cylindrical inner surface being as smooth and reflective as possible. In addition the straight hollow tube may comprise an inner cross section at an input aperture representing the input of the optical signal conductor, in which the input aperture is sufficiently large to capture a pulsating radiant flux signal provided at the output of the optical transmitter in response to the first triggering pulse signal. The optical transmitter providing the pulsating radiant flux signal may transmit during the conducting state an emission of rays, in which the emission of rays may enter at a centre of the input aperture on a longitudinal axis of the straight hollow tube. In addition the optical transmitter may comprise a sufficiently narrow emission angle to reflect all rays being struck on the cylindrical inner surface of the straight hollow tube from the input aperture up to an output aperture, in which the cylindrical outer surface to the cylindrical inner surface of the straight hollow tube may be substantially transparent, and the reflected rays in conjunction with non-reflected rays at angles near as well as on the longitudinal axis defined as a density of rays, in which the density of rays may provide a pulsating radiant flux signal comprising a near uniform high radiant intensity at the output aperture of the straight hollow tube representing the output of the optical signal conductor. According to the optical receiver the input may exhibit a circular optical input comprising a cross section being sufficiently large to capture the pulsating radiant flux signal being provided at the output aperture of the straight hollow tube, in which the first triggering pulse signal having electrical properties may be provided at the output of the optical receiver in response to the pulsating radiant flux signal represented by the first triggering pulse signal having optical properties.

In accordance with the first and second arrangement the transmission link may be implemented with a bi-stable flip-flop circuit being operated by binary signals, in which the output of the first signal conductor may be coupled to a first input of the bi-stable flip-flop circuit for providing the first triggering pulse signal and an output of the second signal conductor may be coupled to a second input of the bi-stable flip-flop circuit for providing the second triggering pulse signal. Subsequently the bi-stable flip-flop circuit may be operable to combine the first triggering pulse signal and the second triggering pulse signal for converting back the pulse modulated control signal provided at an output of the bi-stable flip-flop circuit as will be well understood by those skilled in the art.

A power source component as shown in FIG. 4 BLOCK 4 may comprise a dual voltage source coupled to a crosswise switching charge pump setting part of the charge pump component as shown in FIG. 4 BLOCK 5, in which the dual voltage source may be constituted with a positive voltage terminal, a common voltage terminal and a negative voltage terminal. In addition a voltage provided between the positive voltage terminal and the common voltage terminal may be equal to a voltage provided between the common voltage terminal and the negative voltage terminal, in which the common voltage terminal may provide a reference voltage for the crosswise switching charge pump setting as well as for the switching power converter system.

The dual voltage source may be rated for sourcing power as well as sinking power at both the positive voltage terminal and the negative voltage terminal in conjunction with the common voltage terminal to handle for example complex power, in which a reactive power part of the complex power may dominate an active or real power part of the complex power being handled resulting in a periodic exchange of reactive power between the dual voltage source and the crosswise switching charge pump setting, whereas the active power part being sourced by means of the dual voltage source may be derived from for example the AC mains, a battery supply, a voltage generator or a combination thereof.

From a point of view of the switching power converter system coupled to a load component FIG. 4 BLOCK 6, the load component may comprise a load coupled to the crosswise switching charge pump setting. Subsequently the dual voltage source, the crosswise switching charge pump setting and the load may provide an interactive coherent embodiment for exchanging or transferring power, energy or electrical charge per unit of time, in which by means of interaction the load may be driven in accordance with the specifications as being set. For example the interactive coherent embodiment including the load being complex may handle the complex power characterised of a relationship between the active or real power part and the reactive power part. According to the switching power converter system coupled to the load of the load component FIG. 4 BLOCK 6, the load component may be replaced by a voltage source coupled to the crosswise switching charge pump setting. Subsequently the dual voltage source, the crosswise switching charge pump setting and the voltage source may provide an interactive coherent embodiment for transferring electrical power, electrical energy or electrical charge per unit of time. For example the interactive coherent embodiment including the voltage source being a voltage generator may handle a transfer of electrical charge per unit of time from the voltage generator sourcing electrical energy towards the dual voltage source sinking the electrical energy. Subsequently the dual voltage source may transfer the electrical energy to for example the AC mains, a battery supply, a capacitor bank or a combination thereof.

In accordance with a supporting voltage provided between the positive voltage terminal and the negative voltage terminal of the dual voltage source, the supporting voltage may be set for example manually to a fixed voltage or in response to a galvanic isolated control signal emanated from a microprocessor, in which the supporting voltage may be adjusted over a predefined voltage range to adjust in a proportional degree a summated positive switched voltage as well as a summated negative switched voltage provided at an interlink terminal of the crosswise switching charge pump setting with respect to the reference voltage presented at the common voltage terminal.

According to the power source component comprising the dual voltage source, the dual voltage source may be implemented with a power supply topology being well-known in the art such as for example a linear power supply setting, a switched mode power supply setting (SMPS), a battery supply setting or a combination thereof, in which the power source component may be constituted with for example galvanic isolation means, low pass filter means, protection means, connection means, as well as current limiting means, in which the current limiting means may provide a maximum current limit for the dual voltage source as well as for the interactive coherent embodiment including for example the load as described above.

It is to be noted that the power source component is not limited to an implementation of the dual voltage source as described above and may comprise for example instead of the dual voltage source a single voltage source constituted with an additional centre tap by means of a (active)virtual common voltage terminal.

Needless to say, that the switching power converter system may comprise for example two or more crosswise switching charge pump settings each constituted with a dual voltage source, a dual voltage source constituted with the two or more crosswise switching charge pump settings or a combination thereof, in which the power source component may include an accessory power supply for powering system components of the switching power converter system.

It is to be emphasised that the switching power converter system comprising a configuration of for example an AC to AC (alternating current) converter the power source component may be omitted in whole or in part as will be described hereinafter.

The following embodiments of the present invention encompassing various implementations of the crosswise switching charge pump setting comprising the configuration of the H8H topology will now be described more specifically.

It is to be emphasised that the following descriptions of the present invention with reference to the following embodiments of the various implementations of a crosswise switching charge pump setting are presented herein for purpose of illustration and description only, in which the precise forms disclosed are not intended to be exhaustive or to be limited. In addition the various implementations of a crosswise switching charge pump setting in accordance with the present invention resides not only in any of the following embodiments taken alone, but rather in the particular combination of all of its configurations as well as all of its interrelationships for the functions specified.

It is to be noted, that the term “connected” as being used in the following descriptions of the present invention and in the annexed claims means a direct electrical connection between two electrical elements without any electrical interrupts, whereas the term “coupled” means a direct electrical connection as well as an indirect electrical connection through one or more passive or active intermediary elements.

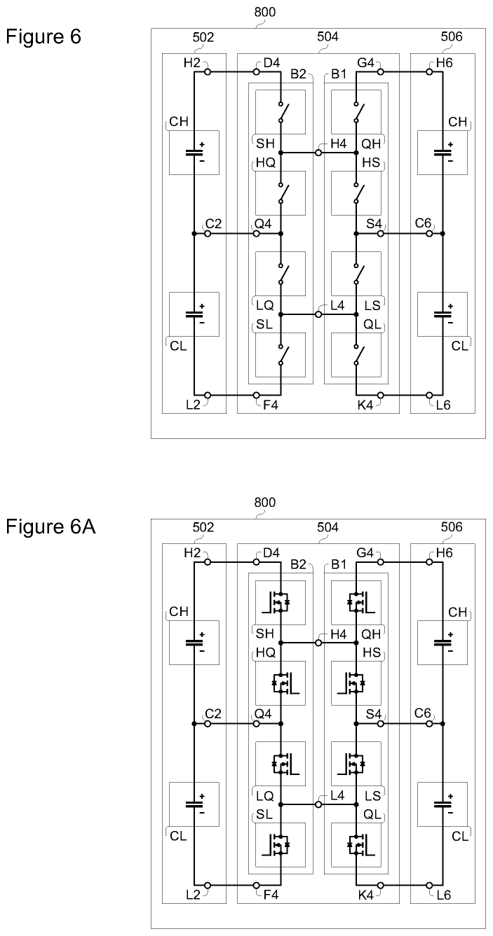

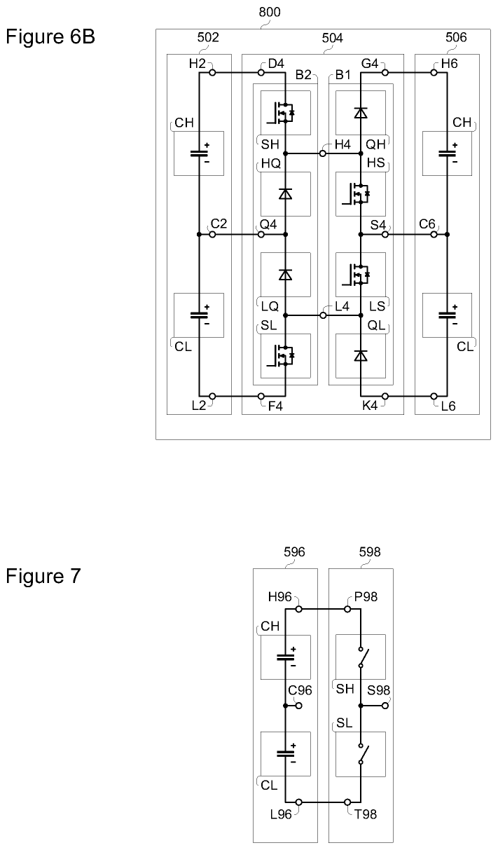

In accordance with the present invention the switching power converter system includes a charge pump component as illustrated in FIG. 4 BLOCK 5 responsive to at least one pulse modulated control signal emanated from the control component as shown in FIG. 4 BLOCK 2, the receiving component as shown in FIG. 4 BLOCK 1 or a combination thereof, in which the charge pump component comprises a crosswise switching charge pump setting implemented with at least two auxiliary units and at least one interlace unit. The crosswise switching charge pump setting may comprise a configuration as shown in FIG. 5 as well as a configuration as shown in FIG. 6 of an interlace unit 504 intermediately coupled in cascade with an auxiliary unit being pre-coupled 502 and an auxiliary unit being post-coupled 506 to form a H8H topology 800, in which the interlace unit 504 is one of the at least one interlace unit, and in which the auxiliary unit being pre-coupled 502 and the auxiliary unit being post-coupled 506 are two of the at least two auxiliary units. The interlace unit of the H8H topology 800 is operable to couple in response to one or more of the at least one pulse modulated control signal the auxiliary unit being pre-coupled with the auxiliary unit being post-coupled repetitively in accordance with a high operational state and a low operational state of the interlace unit. The switching power converter system is characterised in that each of the at least two auxiliary units comprises a high side capacitance section CH and a low side capacitance section CL coupled in series as well as a high side terminal, a common side terminal and a low side terminal, in which the high side capacitance section CH is coupled between the high side terminal and the common side terminal, and in which the low side capacitance section CL is coupled between the common side terminal and the low side terminal. The interlace unit of the H8H topology is operable to couple during the high operational state the high side terminal H2 of the auxiliary unit being pre-coupled with the common side terminal C6 of the auxiliary unit being post-coupled and the common side terminal C2 of the auxiliary unit being pre-coupled with the low side terminal L6 of the auxiliary unit being post-coupled, and the interlace unit is operable to couple during the low operational state the common side terminal C2 of the auxiliary unit being pre-coupled with the high side terminal H6 of the auxiliary unit being post-coupled and the low side terminal L2 of the auxiliary unit being pre-coupled with the common side terminal C6 of the auxiliary unit being post-coupled.

According to each of the at least two auxiliary units included in the crosswise switching charge pump setting the high side capacitance section CH comprises at least one capacitive element coupled between the high side terminal and the common side terminal, and the low side capacitance section CL comprises at least one capacitive element coupled between the common side terminal and the low side terminal. In addition a capacitive element being one of the at least one capacitive element of the high side capacitance section or being one of the at least one capacitive element of the low side capacitance section may be for example a capacitor, a polar capacitor, a bipolar capacitor, an electrolytic capacitor, a ceramic capacitor, a polypropylene film capacitor, a SMT capacitor, a battery or a battery supply. Subsequently two or more capacitive elements being two or more of the at least one capacitive element of the high side capacitance section or being two or more of the at least one capacitive element of the low side capacitance section may be coupled in series, coupled in parallel or a combination thereof, in which for example the two or more capacitive elements coupled in parallel may be substantial identical to form a capacitor bank, the two or more capacitive elements comprising different characteristic properties complementing each other such as a combination of a capacitor capable of fast repetitive charge and discharge cycles during a switching period associated with an operational switching frequency and a battery comprising a very high capacitance rating or a combination thereof, and in which a series coupling of the two or more capacitive elements may provide the means for bridging a higher voltage rating across the series coupling.

According to each of the at least two auxiliary units included in the crosswise switching charge pump setting the high side capacitance section may comprise a capacitive element being one of the at least one capacitive element, a resistive element coupled in series or coupled in parallel with the capacitive element, an inductive element coupled in series or coupled in parallel with the capacitive element or a combination thereof, and the low side capacitance section may comprise a capacitive element being one of the at least one capacitive element, a resistive element coupled in series or coupled in parallel with the capacitive element, an inductive element coupled in series or coupled in parallel with the capacitive element or a combination thereof. As an example the high side capacitance section and the low side capacitance section may include each a parallel coupling of a first branch comprising a resistive element coupled in series with a ceramic capacitor and a second branch comprising an inductive element coupled in series with an electrolytic capacitor to form a R/L, snubber. As a further example two or more capacitive elements being two or more of the at least one capacitive element of the high side capacitance section or being two or more of the at least one capacitive element of the low side capacitance section may be coupled in series, in which each of the two or more capacitive elements may be coupled in parallel with a resistive element for balancing means as well as for discharging means during a shut-down phase. A resistive element included in the high side capacitance section or included in the low side capacitance section may be for example a resistor, a thick film resistor, a carbon resistor, a metal film resistor, a SMT resistor, a printed conductive polymer paste resistor on a printed circuit board (PCB), ESR (Equivalent Series Resistance) or a combination of resistive elements whereas an inductive element may be for example an inductor, a ferrite bead, a wire wound ceramic inductor, a SMT shielded power inductor, inductance of a track on a PCB, ESL (Equivalent Series Inductance) or a combination of inductive elements.

According to the crosswise switching charge pump setting implemented with the at least two auxiliary units and the at least one interlace unit the crosswise switching charge pump setting may comprise a parallel coupling of two or more of the at least two auxiliary units to form a cluster. The parallel coupling of the two or more of the at least two auxiliary units to form the cluster may be implemented by means of the high side terminals coupled, the common side terminals coupled and the low side terminals coupled of the two or more of the at least two auxiliary units.

Furthermore according to the crosswise switching charge pump setting implemented with the at least two auxiliary units and the at least one interlace unit the common side terminal in particular of each of the at least two auxiliary units may be capable to provide a reference voltage, to provide the means for a coupling with for example a load, to provide the means for a coupling of the switching power converter system or a combination thereof.

According to the H8H topology 800 the interlace unit 504 is operable to couple in response to one or more of the at least one pulse modulated control signal the auxiliary unit being pre-coupled 502 with the auxiliary unit being post-coupled 506 repetitively in accordance with the high operational state and the low operational state of the interlace unit, in which a pulse modulated control signal being one of the at least one pulse modulated control signal comprises a switching period associated with an operational switching frequency of the interlace unit. Subsequently the switching period of the pulse modulated control signal may be subdivided in a first period portion and a second period portion by means of a first switched transition and a second switched transition, in which the first period portion initiated by means of the first switched transition may be associated with a generation as well as a duration of the high operational state of the interlace unit, and in which the second period portion initiated by means of the second switched transition may be associated with a generation as well as a duration of the low operational state of the interlace unit.

According to the H8H topology 800 formed by means of the configuration of the interlace unit 504 intermediately coupled in cascade with the auxiliary unit being pre-coupled 502 and the auxiliary unit being post-coupled 506 the interlace unit may be basically implemented with two circuit settings each being operable to couple in response to one or more of the at least one pulse modulated control signal the auxiliary unit being pre-coupled with the auxiliary unit being post-coupled repetitively in accordance with the high operational state and the low operational state of the interlace unit, in which FIG. 5 illustrates the H8H topology comprising a first circuit setting of the interlace unit being preferred, and in which FIG. 6 illustrates the H8H topology comprising a second circuit setting of the interlace unit being an alternative. Furthermore the FIGS. 5C and 5D illustrate the configuration of the H8H topology, in which the auxiliary unit being pre-coupled 502, the auxiliary unit being post-coupled 506 and the interlace unit 504 are adapted in accordance with a variation of a circuit diagram as shown in FIG. 5. The variation may be applicable to a circuit diagram as shown in FIG. 6 as well in an analogous manner.

According to the first circuit setting of the interlace unit 504 intermediately coupled in cascade with the auxiliary unit being pre-coupled 502 and the auxiliary unit being post-coupled 506 to form the H8H topology 800 as shown in FIG. 5 the first circuit setting being preferred may be constituted with a first circuit branch B1 and a second circuit branch B2, in which the first circuit branch B1 and the second circuit branch B2 comprise each at least one high side switching element SH, QH and at least one low side switching element SL, QL coupled in series. Subsequently according to the second circuit branch B2 the at least one high side switching element QH is coupled between a high post side terminal G4 and an access terminal Q4 of the interlace unit, and the at least one low side switching element QL is coupled between the access terminal Q4 and a low post side terminal K4 of the interlace unit, and according to the first circuit branch B1 the at least one high side switching element SH is coupled between a high pre side terminal D4 and an interlink terminal S4 of the interlace unit, and the at least one low side switching element SL is coupled between the interlink terminal S4 and a low pre side terminal F4 of the interlace unit. In addition in accordance with the configuration to form the H8H topology 800 as shown in FIG. 5 the high post side terminal G4 may be coupled to the high side terminal H6 of the auxiliary unit being post-coupled, the access terminal Q4 may be coupled to the common side terminal C2 of the auxiliary unit being pre-coupled, the low post side terminal K4 may be coupled to the low side terminal L6 of the auxiliary unit being post-coupled, the high pre side terminal D4 may be coupled to the high side terminal H2 of the auxiliary unit being pre-coupled, the interlink terminal S4 may be coupled to the common side terminal C6 of the auxiliary unit being post-coupled, and the low pre side terminal F4 may be coupled to low side terminal L2 of the auxiliary unit being pre-coupled. Consequently in accordance with the first circuit setting of the interlace unit 504 intermediately coupled in cascade with the auxiliary unit being pre-coupled 502 and the auxiliary unit being post-coupled 506 to form the H8H topology 800 as shown in FIG. 5 the interlace unit being preferred is operable to couple in response to one or more of the at least one pulse modulated control signal the auxiliary unit being pre-coupled with the auxiliary unit being post-coupled repetitively in accordance with the high operational state and the low operational state of the interlace unit, in which during the high operational state the high side terminal H2 of the auxiliary unit being pre-coupled may be coupled with the common side terminal C6 of the auxiliary unit being post-coupled and the common side terminal C2 of the auxiliary unit being pre-coupled may be coupled with the low side terminal L6 of the auxiliary unit being post-coupled by means of the at least one high side switching element SH of the first circuit branch B1 as well as the at least one low side switching element QL of the second circuit branch B2 being conductive in accordance with the high operational state and the at least one low side switching element SL of the first circuit branch as well as the at least one high side switching element QH of the second circuit branch being non-conductive in accordance with the high operational state, and in which during the low operational state the common side terminal C2 of the auxiliary unit being pre-coupled may be coupled with the high side terminal H6 of the auxiliary unit being post-coupled and the low side terminal L2 of the auxiliary unit being pre-coupled may be coupled with the common side terminal C6 of the auxiliary unit being post-coupled by means of the at least one low side switching element SL of the first circuit branch as well as the at least one high side switching element QH of the second circuit branch being conductive in accordance with the low operational state and the at least one high side switching element SH of the first circuit branch as well as the at least one low side switching element QL of the second circuit branch being non-conductive in accordance with the low operational state.

According to the first circuit setting of the interlace unit 504 as shown in FIG. 5 responsive to one or more of the at least one pulse modulated control signal to generate the high operational state and the low operational state of the interlace unit repetitively the at least one high side switching element SH, QH and the at least one low side switching element SL, QL of both the first circuit branch B1 and the second circuit branch B2 may be constituted with actively driven semiconductors, in which an actively driven semiconductor being one of the actively driven semiconductors may be responsive to a pulse modulated control signal being one of the at least one pulse modulated control signal. As an example each of the actively driven semiconductors SH, SL, QH, QL included in the first circuit branch B1 and the second circuit branch B2 of the first circuit setting of the interlace unit 504 as shown in FIG. 5A may be implemented with a MOSFET responsive to a pulse modulated control signal being one of the at least one pulse modulated control signal. Alternatively the at least one high side switching element QH and the at least one low side switching element QL of the second circuit branch B2 are constituted with passively driven semiconductors QH, QL, and the at least one high side switching element SH and the at least one low side switching element SL of the first circuit branch B1 are constituted with actively driven semiconductors SH, SL, in which an actively driven semiconductor being one of the actively driven semiconductors may be responsive to a pulse modulated control signal being one of the at least one pulse modulated control signal. As an example each of the passively driven semiconductors QH, QL included in the second circuit branch B2 of the first circuit setting of the interlace unit 504 as shown in FIG. 5B may be implemented with a DIODE and each of the actively driven semiconductors SH, SL included in the first circuit branch B1 of the first circuit setting of the interlace unit 504 as shown in FIG. 5B may be implemented with a MOSFET responsive to a pulse modulated control signal being one of the at least one pulse modulated control signal.

According to the second circuit setting of the interlace unit 504 intermediately coupled in cascade with the auxiliary unit being pre-coupled 502 and the auxiliary unit being post-coupled 506 to form the H8H topology 800 as shown in FIG. 6 the second circuit setting being the alternative may be constituted with a first circuit branch B1 and a second circuit branch B2, in which the first circuit branch and the second circuit branch comprise each at least one high side switching element QH, SH, at least one mid high side switching element HS, HQ, at least one mid low side switching element LS, LQ and at least one low side switching element QL, SL coupled in series in this order. Subsequently according to the second circuit branch B2 the at least one high side switching element SH is coupled between the high pre side terminal D4 and a common high side terminal H4 of the interlace unit 504, the at least one mid high side switching element HQ is coupled between the common high side terminal H4 and the access terminal Q4 of the interlace unit, the at least one mid low side switching element LQ is coupled between the access terminal Q4 and a common low side terminal L4 of the interlace unit, and the at least one low side switching element SL is coupled between the common low side terminal L4 and the low pre side terminal F4 of the interlace unit, and according to the first circuit branch B1 the at least one high side switching element QH is coupled between the high post side terminal G4 and the common high side terminal H4 of the interlace unit, the at least one mid high side switching element HS is coupled between the common high side terminal H4 and the interlink terminal S4 of the interlace unit, the at least one mid low side switching element LS is coupled between the interlink terminal S4 and the common low side terminal L4 of the interlace unit, and the at least one low side switching element QL is coupled between the common low side terminal L4 and the low post side terminal K4 of the interlace unit. In addition in accordance with the configuration to form the H8H topology 800 as shown in FIG. 6 the high post side terminal G4 may be coupled to the high side terminal H6 of the auxiliary unit being post-coupled, the access terminal Q4 may be coupled to the common side terminal C2 of the auxiliary unit being pre-coupled, the low post side terminal K4 may be coupled to the low side terminal L6 of the auxiliary unit being post-coupled, the high pre side terminal D4 may be coupled to the high side terminal H2 of the auxiliary unit being pre-coupled, the interlink terminal S4 may be coupled to the common side terminal C6 of the auxiliary unit being post-coupled, and the low pre side terminal F4 may be coupled to low side terminal L2 of the auxiliary unit being pre-coupled. Consequently in accordance with the second circuit setting of the interlace unit 504 intermediately coupled in cascade with the auxiliary unit being pre-coupled 502 and the auxiliary unit being post-coupled 506 to form the H8H topology 800 as shown in FIG. 6 the interlace unit being the alternative is operable to couple in response to one or more of the at least one pulse modulated control signal the auxiliary unit being pre-coupled with the auxiliary unit being post-coupled repetitively in accordance with the high operational state and the low operational state of the interlace unit, in which during the high operational state the high side terminal H2 of the auxiliary unit being pre-coupled may be coupled with the common side terminal C6 of the auxiliary unit being post-coupled and the common side terminal C2 of the auxiliary unit being pre-coupled may be coupled with the low side terminal L6 of the auxiliary unit being post-coupled by means of the at least one high side switching element SH of the second circuit branch, the at least one mid low side switching element LQ of the second circuit branch, the at least one mid high side switching element HS of the first circuit branch as well as the at least one low side switching element QL of the first circuit branch being conductive in accordance with the high operational state, and the at least one mid high side switching element HQ of the second circuit branch, the at least one low side switching element SL of the second circuit branch, the at least one high side switching element QH of the first circuit branch as well as the at least one mid low side switching element LS of the first circuit branch being non-conductive in accordance with the high operational state, and in which during the low operational state the common side terminal C2 of the auxiliary unit being pre-coupled may be coupled with the high side terminal H6 of the auxiliary unit being post-coupled and the low side terminal L2 of the auxiliary unit being pre-coupled may be coupled with the common side terminal C6 of the auxiliary unit being post-coupled by means of the at least one mid high side switching element HQ of the second circuit branch, the at least one low side switching element SL of the second circuit branch, the at least one high side switching element QH of the first circuit branch as well as the at least one mid low side switching element LS of the first circuit branch being conductive in accordance with the low operational state, and the at least one high side switching element SH of the second circuit branch, the at least one mid low side switching element LQ of the second circuit branch, the at least one mid high side switching element HS of the first circuit branch as well as the at least one low side switching element QL of the first circuit branch being non-conductive in accordance with the low operational state.

According to the second circuit setting of the interlace unit 504 as shown in FIG. 6 responsive to one or more of the at least one pulse modulated control signal to generate the high operational state and the low operational state of the interlace unit repetitively the at least one high side switching element QH, SH, the at least one mid high side switching element HS, HQ, the at least one mid low side switching element LS, LQ and the at least one low side switching element QL, SL of both the first circuit branch B1 and the second circuit branch B2 may be constituted with actively driven semiconductors, in which an actively driven semiconductor being one of the actively driven semiconductors may be responsive to a pulse modulated control signal being one of the at least one pulse modulated control signal. As an example each of the actively driven semiconductors QH, SH, HS, HQ, LS, LQ, QL, SL included in the first circuit branch B1 and the second circuit branch B2 of the second circuit setting of the interlace unit 504 as shown in FIG. 6A may be implemented with a MOSFET responsive to a pulse modulated control signal being one of the at least one pulse modulated control signal. Alternatively the at least one mid high side switching element HQ and the at least one mid low side switching element LQ of the second circuit branch B2 as well as the at least one high side switching element QH and the at least one low side switching element QL of the first circuit branch B1 may be constituted with passively driven semiconductors HQ, LQ, QH, QL, and the at least one high side switching element SH and the at least one low side switching element SL of the second circuit branch B2 as well as the at least one mid high side switching element HS and the at least one mid low side switching element LS of the first circuit branch B1 may be constituted with actively driven semiconductors, in which an actively driven semiconductor being one of the actively driven semiconductors may be responsive to a pulse modulated control signal being one of the at least one pulse modulated control signal. As an example each of the passively driven semiconductors HQ, LQ, QH, QL included in the second circuit branch B2 and the first circuit branch B1 of the first circuit setting of the interlace unit 504 as shown in FIG. 6B may be implemented with a DIODE, and each of the actively driven semiconductors SH, SL, HS, LS included in the second circuit branch B2 and the first circuit branch B1 of the first circuit setting of the interlace unit 504 as shown in FIG. 6B may be implemented with a MOSFET responsive to a pulse modulated control signal being one of the at least one pulse modulated control signal.

In accordance with the present invention the charge pump component FIG. 4 BLOCK 5 may be coupled to the power source component FIG. 4 BLOCK 4 to receive a supporting voltage, in which in accordance with the H8H topology 800 as shown in FIG. 5 and FIG. 6 the auxiliary unit being pre-coupled 502 may be coupled to a dual voltage source (not shown) to receive the supporting voltage. The dual voltage source may comprise a positive voltage terminal coupled to the high side terminal H2, a common voltage terminal coupled to the common side terminal C2 and a negative voltage terminal coupled to the low side terminal L2, in which the supporting voltage may be provided between the positive voltage terminal and the negative voltage terminal with respect to a reference voltage presented at the common voltage terminal and therefore the reference voltage presented at the common side terminal C2 of the H8H topology. As a result the high side capacitance section CH of the auxiliary unit being pre-coupled 502 may be charged up to a high side voltage presented between the high side terminal H2 and the common side terminal C2 equal to a voltage provided between the positive voltage terminal and the common voltage terminal of the dual voltage source whereas a low side capacitance section CL of the auxiliary unit being pre-coupled may be charged up to a low side voltage presented between the common side terminal C2 and the low side terminal L2 equal to a voltage provided between the common voltage terminal and the negative voltage terminal of the dual voltage source. Subsequently in operation the interlace unit 504 of the H8H topology 800 is operable to couple during the high operational state in response to one or more of the at least one pulse modulated control signal the high side terminal H2 of the auxiliary unit being pre-coupled 502 with the common side terminal C6 of the auxiliary unit being post-coupled 506 and the common side terminal C2 of the auxiliary unit being pre-coupled with the low side terminal L6 of the auxiliary unit being post-coupled resulting in a parallel coupling of the high side capacitance section CH of the auxiliary unit being pre-coupled 502 and the low side capacitance section CL of the auxiliary unit being post-coupled 506, in which the low side capacitance section of the auxiliary unit being post-coupled may be charged up to a low side voltage presented between the common side terminal C6 and the low side terminal L6 of the auxiliary unit being post-coupled equal to the high side voltage provided between the high side terminal H2 and the common side terminal C2 of the auxiliary unit being pre-coupled by means of transferring an electrical charge. Furthermore in operation the interlace unit 504 of the H8H topology 800 is operable to couple during the low operational state in response to one or more of the at least one pulse modulated control signal the common side terminal C2 of the auxiliary unit being pre-coupled 502 with the high side terminal H6 of the auxiliary unit being post-coupled 506 and the low side terminal L2 of the auxiliary unit being pre-coupled with the common side terminal C6 of the auxiliary unit being post-coupled resulting in a parallel coupling of the low side capacitance section CL of the auxiliary unit being pre-coupled 502 and a high side capacitance section CH of the auxiliary unit being post-coupled 506, in which the high side capacitance section of the auxiliary unit being post-coupled may be charged up to a high side voltage presented between the high side terminal H6 and the common side terminal C6 of the auxiliary unit being post-coupled equal to the low side voltage provided between the common side terminal C2 and the low side terminal L2 of the auxiliary unit being pre-coupled by means of transferring an electrical charge. Consequently by means of the high operational state and the low operational state repeated successively during each switching period of the interlace unit 504 associated with the operational switching frequency both the high side capacitance section CH and the low side capacitance section CL of the auxiliary unit being post-coupled 506 may be charged alternately by means of the auxiliary unit being pre-coupled 502, by means of the dual voltage source or a combination thereof, in which a summation of the high side voltage and the low side voltage presented between the high side terminal H6 and the low side terminal L6 of the auxiliary unit being post-coupled may be equal to the supporting voltage. Subsequently in operation the interlace unit 504 of the H8H topology 800 is operable to couple during the high operational state in response to one or more of the at least one pulse modulated control signal the high side terminal H2 of the auxiliary unit being pre-coupled 502 with the common side terminal C6 of the auxiliary unit being post-coupled 506 and the common side terminal C2 of the auxiliary unit being pre-coupled with the low side terminal L6 of the auxiliary unit being post-coupled resulting in a series coupling of the high side capacitance section CH of the auxiliary unit being pre-coupled 502 and the high side capacitance section CH of the auxiliary unit being post-coupled 506, in which the high side voltage across the high side capacitance section of the auxiliary unit being post-coupled provided between the high side terminal H6 and the common side terminal C6 of the auxiliary unit being post-coupled may be summated with the high side voltage across the high side capacitance section of the auxiliary unit being pre-coupled provided between the high side terminal H2 and the common side terminal C2 of the auxiliary unit being pre-coupled resulting in a summated positive voltage provided at the high side terminal H6 of the auxiliary unit being post-coupled with respect to the reference voltage presented at the common side terminal C2 of the auxiliary unit being pre-coupled by means of summating electrical charge of the respective high side capacitance sections. Furthermore in operation the interlace unit 504 of the H8H topology 800 is operable to couple during the low operational state in response to one or more of the at least one pulse modulated control signal the common side terminal C2 of the auxiliary unit being pre-coupled 502 with the high side terminal H6 of the auxiliary unit being post-coupled 506 and the low side terminal L2 of the auxiliary unit being pre-coupled with the common side terminal C6 of the auxiliary unit being post-coupled resulting in a series coupling of the low side capacitance section CL of the auxiliary unit being pre-coupled 502 and the low side capacitance section CL of the auxiliary unit being post-coupled 506, in which the low side voltage across the low side capacitance section of the auxiliary unit being post-coupled provided between the common side terminal C6 and the low side terminal L6 of the auxiliary unit being post-coupled may be summated with the low side voltage across the low side capacitance section of the auxiliary unit being pre-coupled provided between the common side terminal C2 and the low side terminal L2 of the auxiliary unit being pre-coupled resulting in a summated negative voltage provided at the low side terminal L6 of the auxiliary unit being post-coupled with respect to the reference voltage presented at the common side terminal C2 of the auxiliary unit being pre-coupled by means of summating electrical charge of the respective low side capacitance sections. Consequently by means of the high operational state and the low operational state repeated successively during each switching period of the interlace unit 504 associated with the operational switching frequency the respective high side voltages across the associated high side capacitance sections being summated during the high operational state and the respective low side voltages across the associated low side capacitance sections being summated during the low operational state may result in the summated positive voltage and the summated negative voltage being summated alternately with respect to the reference voltage presented at the common side terminal C2, in which the summated positive voltage as well as the summated negative voltage with respect to the reference voltage is equal to the supporting voltage provided that the respective low side and high side capacitance sections are fully charged, and in which an absolute value of the summated positive voltage with respect to the reference voltage is equal to an absolute value of the summated negative voltage with respect to the reference voltage irrespective of a ratio between the high side voltage and the low side voltage of the auxiliary unit being pre-coupled and therefore the ratio between the low side voltage and the high side voltage of the auxiliary unit being post-coupled provided that the respective low side and high side capacitance sections are fully charged. As an example the auxiliary unit being pre-coupled 502 may provide the high side voltage being 100V and the low side voltage being 50V yielding an imbalance between the high side voltage and the low side voltage. As a result of the H8H topology 800 in operation the auxiliary unit being post-coupled 506 may present the high side voltage being 50V and the low side voltage being 100V, in which during the high operational state of the interlace unit 504 the high side voltage of the auxiliary unit being post-coupled is summated with the high side voltage of the auxiliary unit being pre-coupled resulting in a summated positive voltage of 150V with respect to the reference voltage presented at the common side terminal C2, and in which during the low operational state of the interlace unit 504 the low side voltage of the auxiliary unit being post-coupled is summated with the low side voltage of the auxiliary unit being pre-coupled resulting in a summated negative voltage of −150V with respect to the reference voltage presented at the common side terminal C2. Consequently the summated positive voltage and the summated negative voltage will remain equal in absolute values with respect to the reference voltage of the H8H topology 800 presented at the common side terminal C2 and therefore balanced irrespective of the imbalance in accordance with the ratio between the high side voltage and the low side voltage of the auxiliary unit being pre-coupled, in which a manner of operation of the H8H topology may be characterised as downright stable by means of a self-balancing topology concept.

According to the H8H topology 800 taken alone the interlace unit 504 may generate in accordance with the high operational state and the low operational state a positive switched voltage and a negative switched voltage provided alternately at the interlink terminal S4 of the interlace unit with respect to the reference voltage presented at the common side terminal C2 of the auxiliary unit being pre-coupled 502, in which during the high operational state the interlink terminal S4 may be coupled to the high side terminal H2 of the auxiliary unit being pre-coupled to provide the positive switched voltage with respect to the reference voltage equal to the high side voltage provided between the high side terminal H2 and the common side terminal C2 of the auxiliary unit being pre-coupled, and in which during the low operational state the interlink terminal S4 may be coupled to the low side terminal L2 of the auxiliary unit being pre-coupled to provide the negative switched voltage with respect to the reference voltage equal to the low side voltage provided between the low side terminal L2 and the common side terminal C2 of the auxiliary unit being pre-coupled. The positive switched voltage and the negative switched voltage generated alternately with respect to the reference voltage may be characterised by a first switched voltage transition and a second switched voltage transition of a switching period being associated with an operational switching frequency of the interlace unit, in which during the first switched transition the negative switched voltage changes state to the positive switched voltage by means of changing the low operational state into the high operational state, and in which during the second switched transition the positive switched voltage changes state to the negative switched voltage by means of changing the high operational state into the low operational state.

The interlink terminal S4 of the interlace unit 504 in particular is capable to provide the positive switched voltage and the negative switched voltage alternately with respect to the reference voltage, to provide the means for a coupling with for example a load, to provide the means for a coupling of the switching power converter system or a combination thereof.

According to the variation of the circuit diagram as shown in FIG. 5 the interlace unit 504, the auxiliary unit being pre-coupled 502 and the auxiliary unit being post-coupled 506 to form the H8H topology 800 are adapted as shown in the FIGS. 5C and 5D, in which the first circuit setting being adapted may be constituted with the first circuit branch B1 and the second circuit branch B2, the first circuit branch B1 and the second circuit branch B2 each comprising the at least one high side switching element SH, QH and the at least one low side switching element SL, QL. Subsequently according to the second circuit branch B2 the at least one high side switching element QH is coupled between the high post side terminal G4 and a high side access terminal Q4 of the interlace unit, the at least one low side switching element QL is coupled between a low side access terminal 4Q and the low post side terminal K4 of the interlace unit, according to the first circuit branch B1 the at least one high side switching element SH is coupled between the high pre side terminal D4 and a high side interlink terminal S4 of the interlace unit, and the at least one low side switching element SL is coupled between a low side interlink terminal 4S and the low pre side terminal F4 of the interlace unit. According to the circuit diagram as shown in the FIGS. 5C and 5D the auxiliary unit being pre-coupled 502 and the auxiliary unit being post-coupled 506 may comprise each the high side capacitance section and the low side capacitance section coupled in series between the high side terminal and the low side terminal, in which the coupling between the high side capacitance section and the low side capacitance section may be interposed by a mid high side capacitance section, a mid low side capacitance section, a mid high side terminal, the common side terminal and a mid low side terminal, the high side capacitance section coupled between the high side terminal and the mid high side terminal, the mid high side capacitance section coupled between the mid high side terminal and the common side terminal, the mid low side capacitance section coupled between the common side terminal and the mid low side terminal, and the low side capacitance section coupled between the mid low side terminal and the low side terminal. It is to be noted that the mid high side capacitance section and mid low side capacitance section may comprise all technical features specified for the high side capacitance section and the low side capacitance section. In accordance with the configuration to form the H8H topology 800 as shown in FIG. 5C the high post side terminal G4 may be coupled to the high side terminal H6 of the auxiliary unit being post-coupled, the high side access terminal Q4 may be coupled to the mid low side terminal 2L of the auxiliary unit being pre-coupled, the low side access terminal 4Q may be coupled to the mid high side terminal 2H of the auxiliary unit being pre-coupled, the low post side terminal K4 may be coupled to the low side terminal L6 of the auxiliary unit being post-coupled, the high pre side terminal D4 may be coupled to the high side terminal H2 of the auxiliary unit being pre-coupled, the high side interlink terminal S4 may be coupled to the common side terminal C6 of the auxiliary unit being post-coupled, the low side interlink terminal 4S may be coupled to the common side terminal C6 of the auxiliary unit being post-coupled and the low pre side terminal F4 may be coupled to low side terminal L2 of the auxiliary unit being pre-coupled. In accordance with the configuration to form the H8H topology 800 as shown in FIG. 5D the high post side terminal G4 may be coupled to the high side terminal H6 of the auxiliary unit being post-coupled, the high side access terminal Q4 may be coupled to the mid high side terminal 2H of the auxiliary unit being pre-coupled, the low side access terminal 4Q may be coupled to the mid low side terminal 2L of the auxiliary unit being pre-coupled, the low post side terminal K4 may be coupled to the low side terminal L6 of the auxiliary unit being post-coupled, the high pre side terminal D4 may be coupled to the high side terminal H2 of the auxiliary unit being pre-coupled, the high side interlink terminal S4 may be coupled to the common side terminal C6 of the auxiliary unit being post-coupled, the low side interlink terminal 4S may be coupled to the common side terminal C6 of the auxiliary unit being post-coupled and the low pre side terminal F4 may be coupled to low side terminal L2 of the auxiliary unit being pre-coupled. It is to be noted that aside from an expansion of terminals resulting in an increase of operability as described hereinafter the H8H topology as shown in the FIGS. 5C and 5D may comprise all technical features specified for the configuration of the H8H topology in accordance with the FIGS. 5, 5A and 5B.

In accordance with the present invention the charge pump component FIG. 4 BLOCK 5 may be coupled to the power source component FIG. 4 BLOCK 4 to receive a supporting voltage, in which in accordance with the H8H topology 800 as shown in FIG. 5C and FIG. 5D the auxiliary unit being pre-coupled 502 may be coupled to a dual voltage source (not shown) to receive the supporting voltage. The dual voltage source may comprise a positive voltage terminal coupled to the high side terminal H2, a common voltage terminal coupled to the common side terminal C2 and a negative voltage terminal coupled to the low side terminal L2, in which the supporting voltage may be provided between the positive voltage terminal and the negative voltage terminal with respect to a reference voltage presented at the common voltage terminal and therefore the reference voltage presented at the common side terminal C2 of the H8H topology, in which the supporting voltage is split equally with respect to the reference voltage. As a result a high side voltage provided across the high side capacitance section CH plus a mid high side voltage provided across the mid high side capacitance section HC may be equal to half the supporting voltage and a mid low side voltage provided across the mid low side capacitance section LC plus a low side voltage provided across the low side capacitance section CL may be equal to the other half of the supporting voltage in accordance with the H8H topology 800 as shown in FIG. 5C and FIG. 5D. Subsequently according to the circuit diagram of the H8H topology 800 as shown in FIG. 5C the interlace unit 504 is operable to couple during the high operational state in response to one or more of the at least one pulse modulated control signal the high side terminal H2 of the auxiliary unit being pre-coupled 502 with the common side terminal C6 of the auxiliary unit being post-coupled 506 and the mid high side terminal 2H of the auxiliary unit being pre-coupled with the low side terminal L6 of the auxiliary unit being post-coupled by means of the at least one high side switching element SH of the first circuit branch B1 as well as the at least one low side switching element QL of the second circuit branch B2 being conductive and the at least one low side switching element SL of the first circuit branch as well as the at least one high side switching element QH of the second circuit branch being non-conductive resulting in a parallel coupling of the high side capacitance section CH of the auxiliary unit being pre-coupled 502 with the mid low side capacitance section LC and the low side capacitance section CL of the auxiliary unit being post-coupled 506, in which a summation of a mid low side voltage charged across the mid low side capacitance section LC and a low side voltage charged across the low side capacitance section CL of the auxiliary unit being post-coupled may be equal to the high side voltage provided across the high side capacitance section of the auxiliary unit being pre-coupled by means of transferring an electrical charge to obtain a balance between the high side voltage of the auxiliary unit being pre-coupled and the mid low side voltage as well as the low side voltage of the auxiliary unit being post-coupled. Furthermore the interlace unit 504 is operable to couple during the low operational state in response to one or more of the at least one pulse modulated control signal the mid low side terminal 2L of the auxiliary unit being pre-coupled 502 with the high side terminal H6 of the auxiliary unit being post-coupled 506 and the low side terminal L2 of the auxiliary unit being pre-coupled with the common side terminal C6 of the auxiliary unit being post-coupled by means of the at least one low side switching element SL of the first circuit branch as well as the at least one high side switching element QH of the second circuit branch being conductive and the at least one high side switching element SH of the first circuit branch B1 as well as the at least one low side switching element QL of the second circuit branch B2 being non-conductive resulting in a parallel coupling of the low side capacitance section CH of the auxiliary unit being pre-coupled 502 with the mid high side capacitance section HC and the high side capacitance section CH of the auxiliary unit being post-coupled 506, in which a summation of a mid high side voltage charged across the mid high side capacitance section HC and a high side voltage charged across the high side capacitance section CH of the auxiliary unit being post-coupled may be equal to the low side voltage provided across the low side capacitance section CL of the auxiliary unit being pre-coupled by means of transferring an electrical charge to obtain a balance between the low side voltage of the auxiliary unit being pre-coupled and the mid high side voltage as well as the high side voltage of the auxiliary unit being post-coupled. Consequently according to the circuit diagram as shown in FIG. 5C the H8H topology may be operable to adjust a summation of the high side voltage, the mid high side voltage, the mid low side voltage and the low side voltage presented between the high side terminal H6 and the low side terminal L6 of the auxiliary unit being post-coupled equal to a voltage ranging from zero volt up to the supporting voltage by means of adjusting proportional the mid high side voltage as well as the mid low side voltage of the auxiliary unit being pre-coupled across a voltage range of zero volt up to half the supporting voltage, in which the mid high side voltage as well as the mid low side voltage of the auxiliary unit being pre-coupled may be set by means of for example a zener diode coupled in parallel to at least one capacitive element included in the mid high side capacitance section as well as included in the mid low side capacitance section of the auxiliary unit being pre-coupled as shown in FIG. 5C. According to the circuit diagram of the H8H topology 800 as shown in FIG. 5D the interlace unit 504 is operable to couple in parallel during the high operational state in response to one or more of the at least one pulse modulated control signal the high side capacitance section CH, the mid high capacitance section HC and the mid low capacitance section LC of the auxiliary unit being pre-coupled 502 with the mid low side capacitance section LC and the low side capacitance section CL of the auxiliary unit being post-coupled 506, in which a summation of a mid low side voltage charged across the mid low side capacitance section LC and a low side voltage charged across the low side capacitance section CL of the auxiliary unit being post-coupled may be equal to a summation of the high side voltage provided across the high side capacitance section CH, the mid high side voltage provided across the mid high side capacitance section HC and the mid low side voltage provided across the mid low side capacitance section LC of the auxiliary unit being pre-coupled by means of transferring an electrical charge to obtain a balance between the high side voltage, the mid high side voltage as well as the mid low side voltage of the auxiliary unit being pre-coupled and the mid low side voltage as well as the low side voltage of the auxiliary unit being post-coupled. Furthermore the interlace unit 504 is operable to couple in parallel during the low operational state in response to one or more of the at least one pulse modulated control signal the low capacitance section CL, the mid low capacitance section LC and the mid high side capacitance section HC of the auxiliary unit being pre-coupled 502 with the mid high side capacitance section HC and the high side capacitance section CH of the auxiliary unit being post-coupled 506, in which a summation of a mid high side voltage charged across the mid high side capacitance section HC and a high side voltage charged across the high side capacitance section CH of the auxiliary unit being post-coupled may be equal to a summation of the low side voltage provided across the low side capacitance section CL, the mid low side voltage provided across the mid low side capacitance section LC and the mid high side voltage provided across the mid high side capacitance section HC of the auxiliary unit being pre-coupled by means of transferring an electrical charge to obtain a balance between the low side voltage, the mid low side voltage as well as the mid high side voltage of the auxiliary unit being pre-coupled and the mid high side voltage as well as the high side voltage of the auxiliary unit being post-coupled. Consequently according to the circuit diagram as shown in FIG. 5D the H8H topology may be operable to adjust a summation of the high side voltage, the mid high side voltage, the mid low side voltage and the low side voltage presented between the high side terminal H6 and the low side terminal L6 of the auxiliary unit being post-coupled equal to a voltage ranging from the supporting voltage up to the supporting voltage being doubled by means of adjusting proportional the high side voltage as well as the low side voltage of the auxiliary unit being pre-coupled across a voltage range of zero volt up to half the supporting voltage, in which the high side voltage as well as the low side voltage of the auxiliary unit being pre-coupled may be set by means of for example a zener diode coupled in parallel to at least one capacitive element included in the high side capacitance section CH as well as included in the low side capacitance section CL of the auxiliary unit being pre-coupled 502 as shown in FIG. 5D.

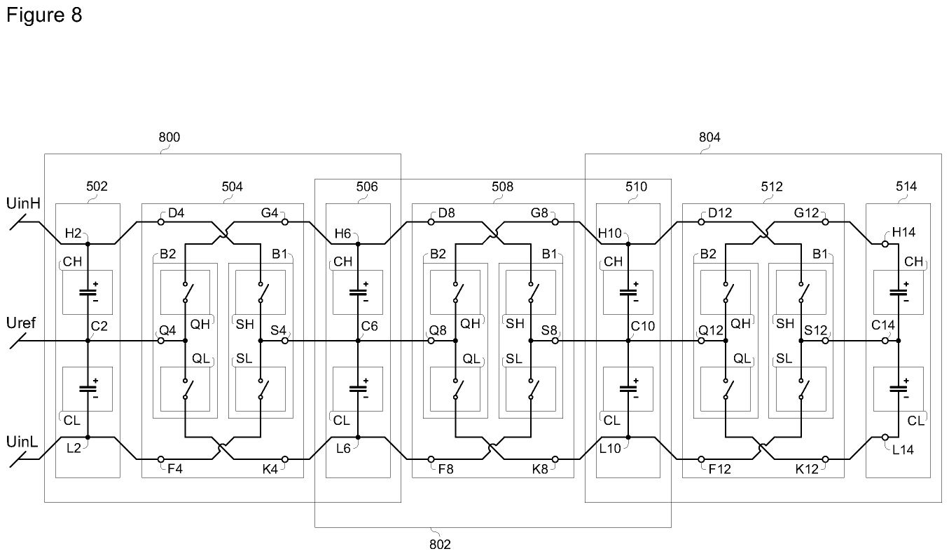

According to the crosswise switching charge pump setting implemented with the at least two auxiliary units and the at least one interlace unit the crosswise switching charge pump setting may be further implemented with an interlink unit, in which the interlink unit may be coupled in cascade with an auxiliary unit being one of the at least two auxiliary units or the auxiliary unit being one of a parallel coupling of two or more of the at least two auxiliary units to form a cluster. In accordance with a circuit diagram as shown in FIG. 7 exhibiting the interlink unit 598 coupled in cascade with the auxiliary unit 596 the interlink unit may be constituted with a circuit branch comprising at least one high side switching element SH and at least one low side switching element SL coupled in series, in which the at least one high side switching element is coupled between a high end terminal P98 and an interlink terminal S98 of the interlink unit, and the at least one low side switching element SL is coupled between the interlink terminal S98 and a low end terminal T98 of the interlink unit. In addition according to FIG. 7 the high end terminal P98 of the interlink unit 598 may be coupled to the high side terminal H96 of the auxiliary unit 596 and the low end terminal T98 of the interlink unit may be coupled to the low side terminal L96 of the auxiliary unit 596. In accordance with the circuit branch of the interlink unit 598 coupled in cascade with the auxiliary unit 596 as shown in FIG. 7 the auxiliary unit 596 may present a high side voltage between the high side terminal H96 and the common side terminal C96 as well as a low side voltage between the common side terminal C96 and the low side terminal L96. Subsequently the interlink unit 598 may be operable to couple in response to one or more of the at least one pulse modulated control signal emanated from the control component as shown in FIG. 4 BLOCK 2 the interlink terminal S98 of the interlink unit with the high side terminal H96 and the low side terminal L96 of the auxiliary unit 596 alternately in accordance with a high operational state and a low operational state of the interlink unit, in which the interlink unit 598 may be operable to couple during the high operational state the interlink terminal S98 with the high side terminal H96 to provide a positive switched voltage at the interlink terminal with respect to a reference voltage presented at the common side terminal C96 equal to the high side voltage by means of the at least one high side switching element SH being conductive and the at least one low side switching element SL being non-conductive, and in which the interlink unit 598 may be operable to couple during the low operational state the interlink terminal S98 with the low side terminal L96 to provide a negative switched voltage at the interlink terminal with respect to a reference voltage presented at the common side terminal C96 equal to the low side voltage by means of the at least one low side switching element SL being conductive and the at least one high side switching element SH being non-conductive.

The interlink terminal S98 of the interlink unit 598 is capable to provide the positive switched voltage and the negative switched voltage alternately with respect to the reference voltage, to provide the means for a coupling with for example a load, to provide the means for a coupling of the switching power converter system or a combination thereof.

According to the circuit branch of the interlink unit the at least one high side switching element and the at least one low side switching element of the circuit branch may be constituted with actively driven semiconductors, in which an actively driven semiconductor being one of the actively driven semiconductors may be responsive to a pulse modulated control signal being one of the at least one pulse modulated control signal.

According to the interlace unit being preferred as shown in FIG. 5, the interlace unit being the alternative as shown in FIG. 6 and the interlink unit as shown in FIG. 7 the first circuit setting in whole or in part and the second circuit setting in whole or in part as well as the circuit branch of the interlink unit in whole may be constituted with actively driven semiconductors, in which the first circuit setting in part as well as the second circuit setting in part may be constituted with passively driven semiconductors as described above. In addition an actively driven semiconductor being one of the actively driven semiconductors may be implemented with for example a TRANSISTOR, a MOSFET, a Silicon Carbide MOSFET, a Gallium Nitride FET, a P-channel enhancement mode field effect transistor or a combination thereof whereas a passively driven semiconductor being one of the passively driven semiconductors may be implemented with for example a DIODE, a Schottky Diode, a dual Diode, a Silicon Carbide Diode, a Transistor (configured as Diode) or a combination thereof, in which two or more of the actively driven semiconductors analogous to two or more of the at least one high side switching element, the at least one mid high side switching element, the at least one mid low side switching element or the at least one low side switching element constituted in the first circuit branch or the second branch of the first circuit setting, the first circuit branch or the second branch of the second circuit setting or the circuit branch of the interlink unit may be coupled in a cascode configuration, coupled in a Darlington configuration, coupled in series for bridging a higher voltage rating across the two or more of the actively driven semiconductors coupled in the series, coupled in parallel for handling a higher electrical current rating, implemented in a switching current-source configuration or a combination thereof, and in which two or more of the passively driven semiconductors analogous to two or more of the at least one high side switching element or the at least one low side switching element of the second circuit branch of the first circuit setting or two or more of the at least one mid high side switching element or the at least one mid low side switching element of the second circuit branch of the second circuit setting or two or more of the at least one high side switching element or the at least one low side switching element of the first circuit branch of the second circuit setting may be coupled in series for bridging a higher voltage rating across the two or more of the passively driven semiconductors coupled in the series, coupled in parallel for handling a higher current rating or a combination thereof.

According to the crosswise switching charge pump setting implemented with at least two auxiliary units and at least one interlace unit the crosswise switching charge pump setting may be configured to form one or more H8H topologies, in which an interlace unit being one of the at least one interlace unit is alternately coupled in cascade with an auxiliary unit being one of the at least two auxiliary units or a cluster comprising a parallel coupling of two or more of the at least two auxiliary units. The parallel coupling of two or more of the at least two auxiliary units to form the cluster may include an auxiliary unit being pre-coupled in cascade with an interlace unit being one of the at least one interlace unit, the parallel coupling of two or more of the at least two auxiliary units to form the cluster may include an auxiliary unit being post-coupled in cascade with an interlace unit being one of the at least one interlace unit or a combination thereof. In addition the crosswise switching charge pump setting may be started as well as ended with an auxiliary unit being one of the at least two auxiliary units, a cluster comprising the parallel coupling of two or more of the at least two auxiliary units or an interlink unit.

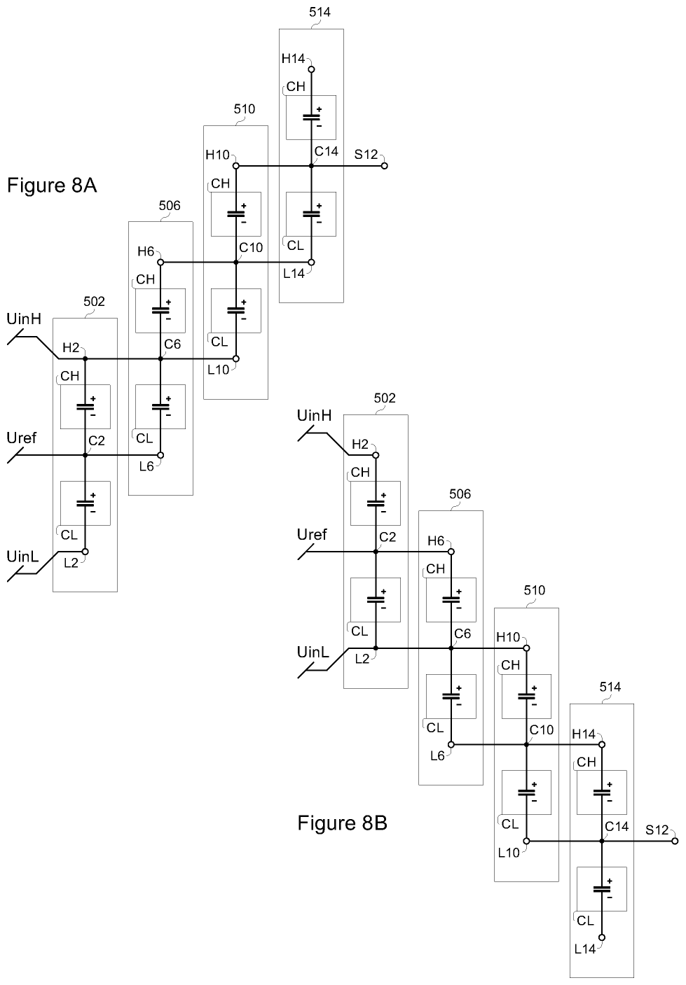

In accordance with the present invention the charge pump component as shown in FIG. 4 BLOCK 5 responsive to at least one pulse modulated control signal emanated from the control component as shown in FIG. 4 BLOCK 2, the receiving component as shown in FIG. 4 BLOCK 1 or a combination thereof includes a crosswise switching charge pump setting implemented with at least two auxiliary units and at least one interlace unit, in which in accordance with a circuit diagram as shown in FIG. 8 the crosswise switching charge pump setting may comprise four auxiliary units being all four of the at least two auxiliary units and three interlace units being all three of the at least one interlace unit. According to the circuit diagram as shown in FIG. 8 each of the at least one interlace unit 504, 508 and 512 is implemented with the first circuit setting being the preferred as shown in FIG. 5. Subsequently the crosswise switching charge pump setting may be constituted by means of each of the at least one interlace unit alternately coupled in cascade with an auxiliary unit being one of the at least two auxiliary units, in which each of the at least one interlace unit is intermediately coupled in cascade with an auxiliary unit being pre-coupled and an auxiliary unit being post-coupled to form three H8H topologies 800, 802 and 804 overlapping one another, and in which the crosswise switching charge pump setting may be started with an auxiliary unit 502 being a first one of the at least two auxiliary units and may be ended with an auxiliary unit 514 being a fourth one of the at least two auxiliary units. In addition the high side terminal H2, the common side terminal C2 and the low side terminal L2 of the auxiliary unit 502 being the first one may form an input of the crosswise switching charge pump setting coupled to an output of a dual voltage source (not shown) in accordance with the power source component FIG. 4 BLOCK 4, in which the output of the dual voltage source may comprise a positive voltage terminal coupled to the high side terminal H2, a common voltage terminal coupled to the common side terminal C2 and a negative voltage terminal coupled to the low side terminal L2 to receive a supporting voltage UinH-UinL between the high side terminal H2 and the low side terminal L2 being split equally with respect to a reference voltage Uref presented at the common side terminal C2, and in which the interlink terminal S12 of an interlace unit 512 being one of the at least one interlace unit in conjunction with the common side terminal C2 of the auxiliary unit 502 being the first one may form an output of the crosswise switching charge pump setting. According to the circuit diagram as shown in FIG. 8 an interlace unit 504 being a first one of the at least one interlace unit is intermediately coupled in cascade with the auxiliary unit 502 being the first one and an auxiliary unit 506 being a second one of the at least two auxiliary units to form a first H8H topology 800, in which the auxiliary unit 502 being the first one is pre-coupled to the interlace unit 504 being the first one by means of the high pre side terminal D4 coupled to the high side terminal H2, the access terminal Q4 coupled to the common side terminal C2 and the low pre side terminal G4 coupled to the low side terminal L2, and in which the auxiliary unit 506 being the second one is post-coupled to the interlace unit 504 being the first one by means of the high post side terminal G4 coupled to the high side terminal H6, the interlink terminal S4 coupled to the common side terminal C6 and the low post side terminal K4 coupled to the low side terminal L6. An interlace unit 508 being a second one of the at least one interlace unit is intermediately coupled in cascade with the auxiliary unit 506 being the second one and an auxiliary unit 510 being a third one of the at least two auxiliary units to form a second H8H topology 802, in which the auxiliary unit 506 being the second one is pre-coupled to the interlace unit 508 being the second one by means of the high pre side terminal D8 coupled to the high side terminal H6, the access terminal Q8 coupled to the common side terminal C6 and the low pre side terminal F8 coupled to the low side terminal L6, and in which the auxiliary unit 510 being the third one is post-coupled to the interlace unit 508 being the second one by means of the high post side terminal G8 coupled to the high side terminal H10, the interlink terminal S8 coupled to the common side terminal C10 and the low post side terminal K8 coupled to the low side terminal L10. An interlace unit 512 being a third one of the at least one interlace unit is intermediately coupled in cascade with the auxiliary unit 510 being the third one and an auxiliary unit 514 being a fourth one of the at least two auxiliary units to form a third H8H topology 804, in which the auxiliary unit 510 being the third one is pre-coupled to the interlace unit 512 being the third one by means of the high pre side terminal D12 coupled to the high side terminal H10, the access terminal Q12 coupled to the common side terminal C10 and the low pre side terminal F12 coupled to the low side terminal L10, and in which the auxiliary unit 514 being the fourth one is post-coupled to the interlace unit 512 being the third one by means of the high post side terminal G12 coupled to the high side terminal H14, the interlink terminal S12 coupled to the common side terminal C14 and the low post side terminal K12 coupled to the low side terminal L14.

From the point of view of the supporting voltage provided between the positive voltage terminal and the negative voltage terminal with respect to the reference voltage presented at the common voltage terminal the crosswise switching charge pump setting is described hereinafter as being in operation, in which the high side capacitance sections CH of 502, CH of 506, CH of 510 and CH of 514 and the low side capacitance sections CL of 502, CL of 506, CL of 510 and CL of 514 of the respective auxiliary units 502, 506, 510 and 514 being dimensioned equally are fully charged in accordance with the supporting voltage being split equally with respect to the reference voltage Uref. As a result the respective high side voltages presented across the associated high side capacitance sections CH of 502, CH of 506, CH of 510 and CH of 514 as well as the respective low side voltages presented across the associated low side capacitance sections CL of 502, CL of 506, CL of 510 and CL of 514 may be equal to the supporting voltage being halved.

In the following description in accordance with the respective H8H topologies 800, 802 and 804 configured for the crosswise switching charge pump setting as shown in FIG. 8 the high operational state as well as the low operational state during a switching period is generated equally at each of the respective interlace units 504, 508 and 512 in response to one or more of the at least one pulse modulated control signal until further notice, in which as a result the crosswise switching charge pump setting may provide Class-D amplification.

From a point of view of the respective H8H topologies 800, 802 and 804 configured for the crosswise switching charge pump setting in operation each H8H topology may comprise during the high operational state of each of the respective interlace units 504, 508 and 512 a series coupling of the high side capacitance sections CH of 502, CH of 506 and CH of 510 of the respective auxiliary units 502, 506 and 510 being pre-coupled with the high side capacitance sections CH of 506, CH of 510 and CH of 514 of the associated auxiliary units 506, 510 and 514 being post-coupled by means of the high side switching elements SH of 504, SH of 508 and SH of 512 as well as the low side switching elements QL of 504, QL of 508 and QL of 512 being conductive and the high side switching elements QH of 504, QH of 508 and QH of 512 as well as the low side switching elements SL of 504, SL of 508 and SL of 512 being non-conductive whereas each H8H topology may comprise during the low operational state of each of the respective interlace units a series coupling of the low side capacitance sections CL of 502, CL of 506 and CL of 510 of the respective auxiliary units 502, 506 and 510 being pre-coupled with the low side capacitance sections CL of 506, CL of 510 and CL of 514 of the associated auxiliary units 506, 510 and 514 being post-coupled by means of the high side switching elements QH of 504, QH of 508, QH of 512 as well as the low side switching elements SL of 504, SL of 508 and SL of 512 being conductive and the high side switching elements SH of 504, SH of 508 and SH of 512 as well as the low side switching elements QL of 504, QL of 508 and QL of 512 being non-conductive, in which the crosswise switching charge pump setting may be characterised as a method for generating during a switching period a summated positive switched voltage as well as a summated negative switched voltage provided at interlink terminal S12 with respect to the reference voltage Uref by means of a summation of the respective high side voltages provided across the associated high side capacitance sections CH of 502, CH of 506 and CH of 510 successively coupled in series between the common side terminal C2 and the interlink terminal S12 during the high operational state resulting in the summated positive switched voltage with respect to the reference voltage Uref as well as by means of a summation of the respective low side voltages provided across the associated low side capacitance sections CL of 502, CL of 506 and CL of 510 successively coupled in series between the common side terminal C2 and the interlink terminal S12 during the low operational state resulting in the summated negative switched voltage with respect to the reference voltage Uref, and in which the crosswise switching charge pump setting may be characterised as a method for sourcing an electrical charge as well as sinking an electrical charge in an equal measure at the interlink terminal S12 in conjunction with the common side terminal C2 presenting the reference voltage Uref by means of each of the respective high side capacitance sections CH of 502, CH of 506 and CH of 510 successively coupled in series between the common side terminal C2 and the interlink terminal S12 during the high operational state as well as each of the respective low side capacitance sections CL of 502, CL of 506 and CL of 510 successively coupled in series between the common side terminal C2 and the interlink terminal S12 during the low operational. It is to be noted that during a switching period the interlink terminal S8 may generating during a switching period a summated positive switched voltage as well as a summated negative switched voltage as well with respect to the reference voltage Uref presented at the common side terminal C2, in which a summation of the respective high side voltages provided across the associated high side capacitance sections CH of 502 and CH of 506 successively coupled in series between the common side terminal C2 and the interlink terminal S8 during the high operational state of each of the at least one interlace unit may result in the summated positive switched voltage with respect to the reference voltage Uref, and in which a summation of the respective low side voltages provided across the associated low side capacitance sections CL of 502 and CL of 506 successively coupled in series between the common side terminal C2 and the interlink terminal S8 during the low operational state of each of the at least one interlace unit may result in the summated negative switched voltage with respect to the reference voltage Uref From the point of view of the respective H8H topologies 800, 802 and 804 configured for the crosswise switching charge pump setting in operation each H8H topology may comprise during the high operational state of each of the respective interlace units 504, 508 and 512 a parallel coupling of the high side capacitance section CH of 502, CH of 506 and CH of 510 of the respective auxiliary units 502, 506 and 510 being pre-coupled with the low side capacitance section CL of 506, CL of 510 and CL of 514 of the associated auxiliary units 506, 510 and 514 being post-coupled by means of the high side switching elements SH of 504, SH of 508 and SH of 512 as well as the low side switching elements QL of 504, QL of 508 and QL of 512 being conductive and the high side switching elements QH of 504, QH of 508 and QH of 512 as well as the low side switching elements SL of 504, SL of 508 and SL of 512 being non-conductive whereas each H8H topology may comprise during the low operational state of each of the respective interlace units a parallel coupling of the low side capacitance section CL of 502, CL of 506 and CL of 510 of the respective auxiliary units 502, 506 and 510 being pre-coupled with the high side capacitance section CH of 506, CH of 510 and CH of 514 of the associated auxiliary units 506, 510 and 514 being post-coupled by means of the high side switching elements QH of 504, QH of 508 and QH of 512 as well as the low side switching elements SL of 504, SL of 508 and SL of 512 being conductive and the high side switching elements SH of 504, SH of 508 and SH of 512 as well as the low side switching elements QL of 504, QL of 508 and QL of 512 being non-conductive, in which the crosswise switching charge pump setting may be characterised as a method for transferring an electrical charge during a switching period between the high side capacitance section of the auxiliary unit being pre-coupled and the low side capacitance section of the auxiliary unit being post-coupled of each H8H topology 800, 802 and 804 during the high operational state to obtain a balance between the high side voltage across the high side capacitance section of the auxiliary unit being pre-coupled and the low side voltage across the low side capacitance section of the auxiliary unit being post-coupled of each H8H topology, and in which the crosswise switching charge pump setting may be characterised as a method for transferring an electrical charge during a switching period between the low side capacitance section of the auxiliary unit being pre-coupled and the high side capacitance section of the auxiliary unit being post-coupled of each H8H topology 800, 802 and 804 during the low operational state to obtain a balance between the high side voltage across the high side capacitance section of the auxiliary unit being post-coupled and the low side voltage across the low side capacitance section of the auxiliary unit being pre-coupled of each H8H topology. As a result an electrical charge may be transferred or pumped in a forward manner from the high side capacitance section of the auxiliary unit being pre-coupled towards the low side capacitance section of the auxiliary unit being post-coupled of each H8H topology during the high operational state and an electrical charge may be transferred or pumped in a backward or inverse manner from the low side capacitance section of the auxiliary unit being post-coupled towards the high side capacitance section of the auxiliary unit being pre-coupled of each H8H topology during the high operational state, and an electrical charge may be transferred or pumped in a forward manner from the low side capacitance section of the auxiliary unit being pre-coupled towards the high side capacitance section of the auxiliary unit being post-coupled of each H8H topology during the low operational state and an electrical charge may be transferred or pumped in a backward or inverse manner from the high side capacitance section of the auxiliary unit being post-coupled towards the low side capacitance section of the auxiliary unit being pre-coupled of each H8H topology during the low operational state. Consequently taken into account the method of an electrical charge being transferred crosswise during a switching period in the forward manner, the backward manner or a combination thereof by means of each of the respective H8H topologies 800, 802 and 804 a mutual effect of the respective H8H topologies for transferring electrical charge by means of the crosswise switching charge pump setting as shown in FIG. 8 may be labelled as ‘transferred in double helix’, in which the mutual effect may be characterised as a self-regulating electrical charge symmetrisation between each of the respective high side capacitance sections CH of 502, CH of 506, CH of 510 and CH of 514 and the respective low side capacitance sections CL of 502, CL of 506, CL of 510 and CL of 514 of the crosswise switching charge pump setting to obtain the balance between each of the respective high side voltages across the associated high side capacitance sections and the respective low side voltages across the associated low side capacitance sections.

FIG. 8A illustrates the manner of the respective high side capacitance sections CH of 502, CH of 506, CH of 510 and CH of 514 and the respective low side capacitance sections CL of 502, CL of 506, CL of 510 and CL of 514 of the crosswise switching charge pump setting being coupled during the high operational state of the respective interlace units 504, 508 and 512 in accordance with the circuit diagram as shown in FIG. 8 whereas FIG. 8B illustrates the manner of the respective high side capacitance sections CH of 502, CH of 506, CH of 510 and CH of 514 and the respective low side capacitance sections CL of 502, CL of 506, CL of 510 and CL of 514 of the crosswise switching charge pump setting being coupled during the low operational state of the respective interlace units 504, 508 and 512 in accordance with the circuit diagram as shown in FIG. 8, in which the circuit diagrams as shown in FIG. 8A and FIG. 8B are limited to the respective high side capacitance sections and the respective low side capacitance sections to best explain the crosswise switching charge pump setting in operation. In a case a load (not shown) is coupled between the interlink terminal S12 of the interlace unit 512 being the third one and the common side terminal C2 of the auxiliary unit 502 being the first one in accordance with the charge pump component as shown in FIG. 4 BLOCK 5 coupled to a load as shown in FIG. 4 BLOCK 6 the summated positive switched voltage and the summated negative switched voltage being generated repetitively during each switching period as provided across the load may maintain well-balanced properties being downright stable in a voltage domain taken advantage of the self-regulating electrical charge symmetrisation, in which the load is for example real or complex in conjunction with the summated positive switched voltage and a summated negative switched voltage being pulse width modulated or the summated positive switched voltage and a summated negative switched voltage comprising a continuous asymmetric duty cycle during each switching period.

In a case the load (not shown) is real driven repetitively during each switching period with the summated positive switched voltage and the summated negative switched voltage emanated from the crosswise switching charge pump setting as shown in FIG. 8 an electrical charge per unit of time may flow alternately through the load in response to the summated positive switched voltage and the summated negative switched voltage being equal to the electrical charge per unit of time transferred at the interlink terminal S12 of the third H8H topology 804, in which the electrical charge per unit of time transferred at the interlink terminal S12 with respect to the electrical charge per unit of time being transferred at an interlink terminal S4 of the first H8H topology 800 is inversely proportional to the summated positive switched voltage and the summated negative switched voltage provided alternately at the interlink terminal S12 with respect to a positive switched voltage and a negative switched voltage provided alternately at the interlink terminal S4. As a result the first H8H topology 800 may determine a power rating for the crosswise switching charge pump setting equal to a power rating of the load divided by an efficiency coefficient of the crosswise switching charge pump setting, in which the efficiency coefficient will be determined by for example switching loss during each transition, conduction loss due to internal resistance and loss due to diode forward voltage. Subsequently each of the respective H8H topologies 800, 802 and 804 may be rated proportionally with respect to power handling and therefore a proportional transfer of the electrical charge per unit of time (electrical current) at each interlink terminal S4, S8 and S12 of the respective H8H topologies, in which for example the respective interlace units 504, 508 and 512 may be rated proportionally in a decreasing order in accordance with a decreasing number of actively driven semiconductors coupled in parallel to handle a proportional lower electrical current rating, and in which for example the respective auxiliary units 502, 506, 510 and 514 may be rated proportionally in a decreasing order in accordance with a decreasing number of electrolytic capacitors coupled in parallel to handle a proportional lower ripple current rating. Consequently the at least one high side switching element as well as the at least one low side switching element of the first branch as well as the second branch may comprise each for example three actively driven semiconductors coupled in parallel for the interlace unit 504 being the first one, two actively driven semiconductors coupled in parallel for the interlace unit 508 being the second one and one actively driven semiconductor for the interlace unit 512 being the third one to be rated proportionally in the decreasing order, in which as a result the implementation of each of the respective H8H topologies may not be substantial identical.

In a case the load (not shown) is subdivided in for example a first load part comprising a series connection of an inductor and a capacitor to form a LC low pass filter for driving a second load part in a low frequency domain within an operational bandwidth as set, in which the series connection may be coupled between the interlink terminal S12 and the common side terminal C2, and in which the second load part coupled in parallel with the capacitor may be coupled between the common side terminal C2 and a node between the inductor and the capacitor of the series connection. Subsequently the load may be driven repetitively during each switching period with the summated positive switched voltage and the summated negative switched voltage emanated from the crosswise switching charge pump setting as shown in FIG. 8, in which the LC low pass filter may be forced to act as a passive integrator provided that an operational switching frequency of the summated positive switched voltage and the summated negative switched voltage provided across the load is typically a factor of 5 to 500 higher with respect to a high end frequency of the operational bandwidth, and in which the LC low pass filter may minimise electromagnetic interference from being radiated and conducted as will be well understood by those skilled in the art.

In accordance with the respective H8H topologies 800, 802 and 804 configured for the crosswise switching charge pump setting as shown in FIG. 8 each of the respective interlace units 504, 508 and 512 may be implemented with the first circuit setting as shown in FIG. 5A comprising the first branch and the second branch each constituted with two MOSFETS each actively driven in response to a pulse modulated control signal, in which a functionality of the crosswise switching charge pump setting in operation as described above may remain substantial identical. Alternatively each of the respective interlace units 504, 508 and 512 may be implemented with the second circuit setting as shown in FIG. 5B comprising the first branch constituted with two MOSFETS each actively driven in response to a pulse modulated control signal and the second branch constituted with two DIODES passively driven resulting in a less complex implementation of the respective H8H topologies 800, 802 and 804 configured for the crosswise switching charge pump setting, in which the functionality of the crosswise switching charge pump setting in operation as described above will be limited in operation due to the introduction of a threshold voltage drop across each DIODE in a forward-biased or conducting state, and in which the functionality of the crosswise switching charge pump setting in operation as described above will be limited in operation due to the lack of an ability to transfer an electrical charge in the backward or inverse manner from the low side capacitance section CL of 506, CL of 510 and CL of 514 of the auxiliary unit 506, 510 and 514 being post-coupled towards the high side capacitance section CH of 502, CH of 506 and CH of 510 of the auxiliary unit being pre-coupled 502, 506 and 510 as well as from the high side capacitance section CH of 506, CH of 510 and CH of 514 of the auxiliary unit being post-coupled 506, 510 and 514 towards the low side capacitance section CL of 502, CL of 506 and CL of 510 of an auxiliary unit being pre-coupled 502, 506 and 510 of each of the respective H8H topologies. However by means of implementing the second circuit setting for each of the respective interlace units omitting an electrical charge from being transferred in the backward or inverse manner as described above the method for sourcing an electrical charge as well as sinking an electrical charge in an equal measure at for example the interlink terminal S12 in conjunction with the common side terminal C2 by means of each of the respective high side capacitance sections CH of 502, CH of 506 and CH of 510 successively coupled in series between the common side terminal C2 and the interlink terminal S12 during the high operational state as well as each of the respective low side capacitance sections CL of 502, CL of 506 and CL of 510 successively coupled in series between the common side terminal C2 and the interlink terminal S12 during the low operational may still be valid.

In the following description in accordance with the respective H8H topologies 800, 802 and 804 configured for the crosswise switching charge pump setting as shown in FIG. 8 the high operational state and the low operational state may be generated independently and yet interrelated at each of the respective interlace units 504, 508 and 512 in response to one or more of the at least one pulse modulated control signal in which as a result the crosswise switching charge pump setting may provide Class-D amplification, Class-G amplification or a combination thereof to provide Class-H amplification.

One or more of the at least one pulse modulated control signal configured for each of the respective interlace units 504, 508 and 512 may be exclusively specified in a time domain as well as in a frequency domain, in which the high operational state and the low operational state may be generated at each of the respective interlace units at different times. In addition one or more of the at least one pulse modulated control signal configured for each of the respective interlace units may be associated with for example a bit being one of a set of bits, in which the respective interlace units may be responsive to the set of bits in accordance with a pulse modulator setting being multi-bit configured, and in which the set of bits may be derived from a digital formatted input signal presented at an input of the switching power converter system. As a result each of the respective H8H topologies 800, 802 and 804 may be driven in combination with one another in response to one or more of the at least one pulse modulated control signal to generate a summated positive switched voltage as well as a summated negative switched voltage provided at interlink terminal S12 with respect to the reference voltage presented at the common side terminal C2, in which the summated positive switched voltage as well as the summated negative switched voltage may be a resulting voltage summated at different voltage levels to provide gradient capabilities in accordance with for example the set of bits.

In general terms in accordance with the present invention each of N H8H topologies configured for a crosswise switching charge pump setting implemented with at least two auxiliary units and at least one interlace unit may be driven in combination with one another in response to one or more of the at least one pulse modulated control signal to provide base two to the exponent N switched combinations and a resulting voltage summated at N plus one different voltage levels, in which the resulting voltage is provided at the interlink terminal of the Nth H8H topology with respect to a reference voltage presented at the common side terminal of an auxiliary unit being a first one of the at least two auxiliary units, and in which N is an integer larger than or equal to two. In further general terms in accordance with the present invention each of N H8H topologies and an interlink unit configured for a crosswise switching charge pump setting implemented with at least two auxiliary units and at least one interlace unit may be driven in combination with one another in response to one or more of the at least one pulse modulated control signal to provide base two to the exponent (N plus one) switched combinations and a resulting voltage summated at N plus two different voltage levels, in which the resulting voltage is provided at the interlink terminal of the interlink unit with respect to a reference voltage presented at the common side terminal of an auxiliary unit being a first one of the at least two auxiliary units, and in which N is an integer larger than or equal to one. In addition the N plus one different voltage levels or the N plus two different voltage levels may generate a minimum voltage step between the different voltage levels equal to a supporting voltage provided between the high side terminal and the low side terminal of the auxiliary unit being the first provided that the supporting voltage is equally divided with respect to the reference voltage, in which a voltage level being one of the N plus one different voltage levels may be equal to the reference voltage provided that N is an even number, and in which a voltage level being one of the N plus two different voltage levels may be equal to the reference voltage provided that N is an odd number.

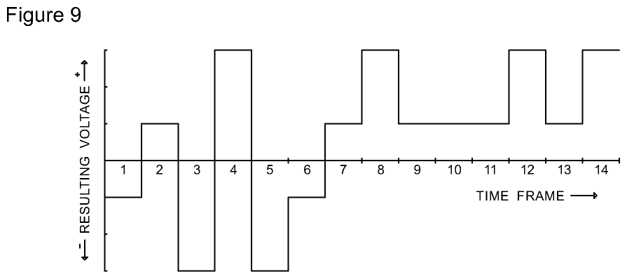

According to the crosswise switching charge pump setting as shown in FIG. 8 each of the respective H8H topologies 800, 802 and 804 may be driven in combination with one another in response to one or more of the at least one pulse modulated control signal to provide eight switched combinations and a resulting voltage summated at four different voltage levels, in which the resulting voltage is provided at the interlink terminal S12 of the third H8H topology with respect to the reference voltage presented at the common side terminal C2 of the auxiliary unit being the first one, and in which N is equal to three. Subsequently as an example the resulting voltage at the interlink terminal S12 may be generated arbitrarily during a time frame as shown in FIG. 9 by means of the high operational state or the low operational state being generated at each of the respective interlace units driven in combination with one another in response to one or more of the at least one pulse modulated control signal in accordance with the time frame being one of the fourteen timeframes as shown in Table 1 corresponding with the timeframes as shown in FIG. 9.

TABLE 1

| | High/Low operational state of the interlace unit being | | |
|---|---|---|---|
| Time frame | the first one | the second one | the third one |
| 1 | High | Low | Low |
| 2 | Low | High | High |
| 3 | Low | Low | Low |
| 4 | High | High | High |
| 5 | Low | Low | Low |
| 6 | Low | Low | High |
| 7 | High | High | Low |
| 8 | High | High | High |
| 9 | High | Low | High |
| 10 | Low | High | High |
| 11 | High | High | Low |
| 12 | High | High | High |
| 13 | High | Low | High |
| 14 | High | High | High |

It is to be noted that the switched combinations being changed may result in the resulting voltage from being unchanged and therefore maintaining a voltage level being one of the four different voltage levels as shown in FIG. 9 in conjunction with Table 1 for example during the time frames 9, 10 and 11 provided that two H8H topologies being two of the respective H8H topologies 800, 802 and 804 comprise opposite operational states. Subsequently the resulting voltage being unchanged may provide a DC voltage with respect to the reference voltage as set, in which the switched combinations may be changed in accordance with the two H8H topologies comprising the opposite operational states that will change simultaneously to cancel out for example a positive switched voltage generated between the interlink terminal and the common side terminal of the auxiliary unit being pre-coupled of one of the two H8H topologies during the high operational state with a negative switched voltage generated between the interlink terminal and the common side terminal of the auxiliary unit being pre-coupled of the other one of the two H8H topologies during the low operational state being the opposite operational state of the high operational state. Therefore the two H8H topologies comprising the opposite operational states that will change simultaneously may form a pair to nullify a switched voltage summation of the positive switched voltage and the negative switched voltage to maintain a status quo of the switched voltage summation being nullified. Consequently in accordance with the crosswise switching charge pump setting as shown in FIG. 8 the respective H8H topologies 800, 802 and 804 may form three pairs of two H8H topologies 800/802, 800/804 and 802/804 alternately in response to three or more of the at least one pulse modulated control signal, in which the high operational state or the low operational state may be changed simultaneously at two of the respective interlace units to form a different pair out of the three pairs. As a result of the three pairs formed alternately in response to the three or more of the at least one pulse modulated control signal the high side capacitance section and the low side capacitance section of each of the respective auxiliary units 506, 510 and 514 excluding the auxiliary unit being the first one 502 may be charged repetitively in accordance with an operational switching frequency to maintain the resulting voltage being unchanged with respect to the reference voltage.

In accordance with the present invention the charge pump component as shown in FIG. 4 BLOCK 5 responsive to at least one pulse modulated control signal emanated from the control component as shown in FIG. 4 BLOCK 2, the receiving component as shown in FIG. 4 BLOCK 1 or a combination thereof includes a crosswise switching charge pump setting implemented with at least two auxiliary units and at least one interlace unit, in which the crosswise switching charge pump setting may be operable to form pairs of two H8H topologies for providing several applications such as for example N H8H topologies each driven in combination with one another in response to one or more of the at least one pulse modulated control signal to provide base two to the exponent N switched combinations and a resulting voltage summated at N plus one different voltage levels for implementing a DC/DC converter. Subsequently two or more pairs of two H8H topologies may be formed simultaneously to maintain the transfer of electrical charge in conjunction with the status quo of a switched voltage summation being nullified, in which a supporting voltage may be presented at an input of the DC/DC converter between the high side terminal and the low side terminal in conjunction with the common side terminal of an auxiliary unit being a first one of the at least two auxiliary units forming the input and furthermore in accordance with a voltage level being one of the N plus one different voltage levels contemplated a DC voltage being the resulting voltage may be provided at an output of the DC/DC converter between the interlink terminal being a Nth one of the N H8H topologies and the common side terminal of the auxiliary unit being the first one forming the output. Needless to say that an increasing number for N may provide an increasing number of different voltage levels allowing an increase of resolution for the resulting voltage being summated in conjunction with a decreasing supporting voltage presented at the input of the DC/DC converter. In addition the N H8H topologies to form the DC/DC converter for the functions specified may be adapted with M H8H topologies being M of the N H8H topologies, M being an integer number smaller than or equal to N, in which each of the M H8H topologies may comprise equal operational states that may change simultaneously in response to one or more of the at least one pulse modulated control signal being pulse width modulated to generate with respect to the reference voltage a summated positive switched voltage and a summated negative switched alternately superimposed on the resulting voltage in part representing a voltage level being one of the N plus one different voltage levels. Furthermore a series connection of an inductor and a capacitor may form a first load part comprising a LC low pass filter for driving a second load part in a low frequency domain within an operational bandwidth as set in accordance with the charge pump component as shown in FIG. 4 BLOCK 5 coupled to a load as shown in FIG. 4 BLOCK 6, in which the series connection may be coupled between the interlink terminal being the Nth one of the N H8H topologies and the common side terminal of the auxiliary unit being the first one, and in which the second load part coupled in parallel with the capacitor may be coupled between the common side terminal of the auxiliary unit being the first one and a node between the inductor and the capacitor of the series connection. Subsequently the summated positive switched voltage and the summated negative switched voltage alternately superimposed on the resulting voltage in part to generate the resulting voltage in full with respect to the reference voltage may force the LC low pass filter to act as a passive integrator. Consequently by means of the LC low pass filter acting as a passive integrator a DC voltage being substantial may be regulated across the second load part within the operational bandwidth as set. It is to be noted that the summated positive switched voltage and a summated negative switched voltage being pulse width modulated may regulate the DC voltage within a voltage range equal to M multiplied with the minimum voltage step of the N plus one different voltage levels.

A further application in accordance with the N H8H topologies possibly adapted with the M H8H topologies being M of the N H8H topologies, supplemented with the interlink unit or a combination thereof to implement a crosswise switching charge pump setting for the switching power converter system may be for example a High Voltage power DAC (digital analogue converter) for direct driving a capacitive load of an electrostatic loudspeaker or a DC/AC converter, in which the crosswise switching charge pump setting may generate a sequence of for example N plus one different voltage levels over time to constitute within an operational bandwidth as set any arbitrary signal flow provided at the interlink terminal being a Nth one of the N H8H topologies with respect to a reference voltage presented at the common side terminal of an auxiliary unit being a first one. An output of the DC/AC converter may be coupled to for example a power grid of the mains being single-phased, in which the interlink terminal being the Nth one of the crosswise switching charge pump setting in conjunction with the common side terminal of the auxiliary unit being the first one may form the output, and in which the respective terminals of the auxiliary unit being the first one of the crosswise switching charge pump setting may form an input of the DC/AC converter. The interlink terminal of the output may be coupled to a line wire of the power grid possibly interposed by means of an inductor to smooth an electrical charge flow per unit of time, in which the common side terminal of the output may be coupled to a neutral wire of the power grid. Subsequently the crosswise switching charge pump setting of the DC/AC converter being grid-tied may be responsive to a feedback signal emanated from a line voltage presented at the line wire with respect to the reference voltage presented at the neutral wire to generate the resulting voltage substantial equal to the line voltage, in which the resulting voltage may be generated to cause an over-voltage condition of the line voltage for providing electrical power to the power grid and therefore transferring electrical charge towards the output of the DC/AC converter, and in which the resulting voltage may be generated to cause an under-voltage condition of the line voltage for taking electrical power of the power grid and therefore transferring electrical charge towards the input of the DC/AC converter.

In addition the input of the DC/AC converter being grid-tied may be coupled to an output of an AC/DC converter constituted with three crosswise switching charge pump settings in a three-phase star configuration each implemented with at least two auxiliary units, at least one interlace unit, an interlink unit and N H8H topologies. The high side terminal, the common side terminal and the low side terminal of an auxiliary unit being a first one of the at least two auxiliary units of a crosswise switching charge pump setting being one of the three crosswise switching charge pump settings may form an output for the crosswise switching charge pump setting, in which the high side terminals may be coupled to one another, the common side terminals may be coupled to one another and the low side terminals may be coupled to one another of each auxiliary unit being the first one of the three crosswise switching charge pump settings to form the output of the AC/DC converter. It is to be noted that the high side terminals coupled to one another, the common side terminals coupled to one another and the low side terminals coupled to one another of each auxiliary unit being the first one may form a parallel coupling of each auxiliary unit being the first one, in which the parallel coupling of each auxiliary unit being the first one may be implemented as one auxiliary unit being a first one for each of the three crosswise switching charge pump settings. Consequently each first H8H topology of the three crosswise switching charge pump settings may overlap each other. The interlink terminal of the interlink unit being a last one and the common side terminal of the auxiliary unit being the first one of a crosswise switching charge pump setting being one of the three crosswise switching charge pump settings may form an input of the crosswise switching charge pump setting, in which the interlink terminal of the interlink unit being the last one of each of the three crosswise switching charge pump settings may form an input of the AC/DC converter. To couple the output of the AC/DC converter with the input of the DC/AC converter each auxiliary unit being the first one of the three crosswise switching charge pump settings of the AC/DC converter may be coupled in parallel with the auxiliary unit being the first one of the crosswise switching charge pump setting of the DC/AC converter by means of the high side terminals coupled to one another, the common side terminals coupled to one another and the low side terminals coupled to one another to form a cluster comprising the parallel coupling of two or more auxiliary units, in which each auxiliary unit being the first one of the three crosswise switching charge pump settings of the AC/DC converter and the auxiliary unit being the first one of the crosswise switching charge pump setting of the DC/AC converter may be implemented as one auxiliary unit. The input of the AC/DC converter may be coupled to three phase wires forming an output of a three phased AC generator, in which each of the respective interlink terminals of the input of the AC/DC converter may be coupled to a phase wire being one of the three phase wires. Subsequently the three crosswise switching charge pump settings being generator-tied may be responsive to feedback signals emanated from line voltages each presented at a phase wire being one of the three phase wires to generate resulting voltages each provided at one of the respective interlink terminals of the input of the AC/DC converter, in which the resulting voltages may be generated to cause an under-voltage condition of the line voltages for taking electrical power of the three phased AC generator and therefore transferring electrical charge from the input towards the output of the AC/DC converter. The combination of the AC/DC converter and the DC/AC converter to form an AC/AC converter may be characterised as a poly-phase configuration configured for the switching power converter system, in which electrical charge may be transferred from an input of the AC/AC converter being the input of the AC/DC converter to an output of the AC/AC converter being the output of the DC/AC converter, and in which by means of the output of the AC/DC converter coupled with the input of the DC/AC converter the AC/AC converter may be powered by for example a power grid connected to the output of the AC/AC converter, an electrical generator connected to the input of the AC/AC converter or a combination thereof omitting the use of the power source component as shown in FIG. 4 BLOCK 4 in whole or in part.

It is to be noted that the present invention is mainly explained in accordance with an output formed by means of the interlink terminal of an interlace unit being a last one or the interlink terminal of an interlink unit being a last one of a crosswise switching charge pump setting, in which an input may be formed by means of the respective terminals of an auxiliary unit being a first one of the crosswise switching charge pump setting. However as described above for the AC/DC converter an input may be formed by means of the interlink terminal of an interlink unit being a last one of a crosswise switching charge pump setting as well in conjunction with an output formed by means of the respective terminals of an auxiliary unit being a first one of the crosswise switching charge pump setting. Therefore it is to be emphasised that according to a crosswise switching charge pump setting implemented with at least two auxiliary units and at least one interlace unit the high side terminal, the common side terminal or the low side terminal of an auxiliary unit being one of the at least two auxiliary units, the access terminal or the interlink terminal of an interlace unit being one of the at least one interlace unit, the interlink terminal of an interlink unit or a combination thereof may form an input, an output or a part thereof of the crosswise switching charge pump setting, in which an input or an output being specified is merely to indicate a direction of real power to be transferred irrespective of the implementations specified for the respective crosswise switching charge pump settings as presented. Only exception to the rule as stated above is an input formed by means of the high side terminal, the low side terminal and the common side terminal of the auxiliary unit being post-coupled configured for a H8H topology implemented in accordance with the first circuit setting as shown in FIG. 5B or the second circuit setting as shown in FIG. 6B, in which a supporting voltage provided between the high side terminal and the low side terminal in conjunction with the common side terminal of the input will not allow the H8H topology to operate properly.

In accordance with the further aspect of the present invention a crosswise switching charge pump setting implemented with at least two auxiliary units and at least one interlace unit may comprise the parallel coupling of two or more of the at least two auxiliary units to form a cluster, in which the cluster comprising the parallel coupling of two or more of the at least two auxiliary units may further comprise low pass filter means, resonant filter means, voltage regulator means, protection means, inrush current limiter means, current monitoring means or a combination thereof.

According to the further aspect of the present invention a cluster comprising the parallel coupling of two or more of the at least two auxiliary units may further comprise the low pass filter means subdivided in high side low pass filter means and low side low pass filter means, in which two auxiliary units included in the parallel coupling of the cluster may comprise a coupling between the high side terminals interposed by the high side low pass filter means, a coupling of the common side terminals and a coupling between the low side terminals interposed by the low side low pass filter means to set an attenuated frequency range between the high side terminals being interposed as well as to set an attenuated frequency range between the low side terminals being interposed. Subsequently a crosswise switching charge pump setting implemented with at least two auxiliary units and at least one interlace unit is configured to form a H8H topology of an interlace unit intermediately coupled in cascade with an auxiliary unit being pre-coupled and an auxiliary unit being post-coupled, in which the auxiliary unit being pre-coupled in cascade with the interlace unit is included in a parallel coupling of two or more of the at least two auxiliary units to form a cluster being pre-coupled to the interlace unit, and in which the auxiliary unit being post-coupled in cascade with the interlace unit is included in a parallel coupling of two or more of the at least two auxiliary units to form a cluster being post-coupled to the interlace unit. Consequently in case the cluster being pre-coupled as well as the cluster being post-coupled further includes high side low pass filter means and low side low pass filter means in a manner as described above, than the configuration of the H8H topology supplemented with snubber means may result in highly improved characteristic switching properties in a high frequency (HF) range of the interlace unit providing fast well-balanced transition times during switching, an absence of any ringing, and reduced electromagnetic interference (EMI). In addition the cluster being pre-coupled as well as the cluster being post-coupled further including high side low pass filter means and low side low pass filter means in a manner as described above may provide the means for increasing a physical distance between two of the at least one interlace unit as well as between one of the at least one interlace unit and an interlink unit without compromising the characteristic switching properties, in which an increase of the physical distance may provide the means for passive cooling as well as for an extended capacitance of one or more of the at least two auxiliary units.

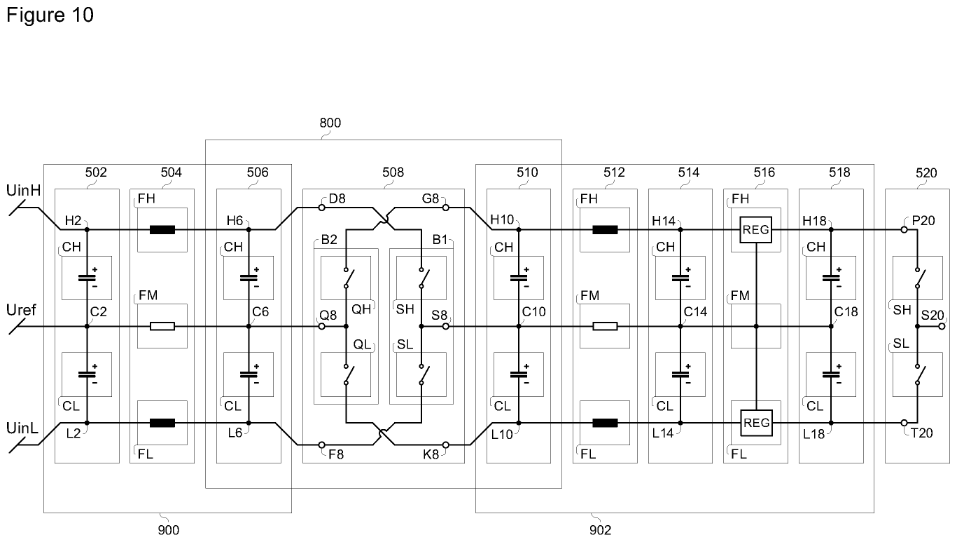

In accordance with the present invention the charge pump component as shown in FIG. 4 BLOCK 5 responsive to at least one pulse modulated control signal emanated from the control component as shown in FIG. 4 BLOCK 2, the receiving component as shown in FIG. 4 BLOCK 1 or a combination thereof includes a crosswise switching charge pump setting implemented with at least two auxiliary units and at least one interlace unit, in which in accordance with a circuit diagram as shown in FIG. 10 the crosswise switching charge pump setting comprises five auxiliary units 502, 506, 510, 514 and 518 being all five of the at least two auxiliary units, an interlace unit 508 being an only one of the at least one interlace unit and an interlink unit 520. According to the circuit diagram as shown in FIG. 10 a parallel coupling of an auxiliary unit 502 being a first one and an auxiliary unit 506 being a second one may form a first cluster 900 by means of a coupling between the high side terminals H2 and H6 interposed by a high side adjust section FH of a regulating unit 504, a coupling between the common side terminals C2 and C6 interposed by a mid side adjust section FM of the regulating unit 504 and a coupling between the low side terminals L2 and L6 interposed by a low side adjust section FL of the regulating unit 504, in which the auxiliary unit 502 being the first one and the auxiliary unit 506 being the second one are two of the at least two auxiliary units, and in which the regulating unit 504 is included in the first cluster 900. Furthermore a parallel coupling of an auxiliary unit 510 being a third one, an auxiliary unit 514 being a fourth one and an auxiliary unit 518 being a fifth one may form a second cluster 902 by means of a coupling between the high side terminals H10 and H14 interposed by a high side adjust section FH of a regulating unit 512, a coupling between the common side terminals C10 and C14 interposed by a mid side adjust section FM of the regulating unit 512, a coupling between the low side terminals L10 and L14 interposed by a low side adjust section FL of the regulating unit 512, a coupling between the high side terminals H14 and H18 interposed by a high side adjust section FH of a regulating unit 516, a coupling between the common side terminals C14 and C18 interposed by a mid side adjust section FM of the regulating unit 516 and a coupling between the low side terminals L14 and L18 interposed by a low side adjust section FL of the regulating unit 516, in which the auxiliary unit 510 being the third one, the auxiliary unit 514 being the fourth one and the auxiliary unit 518 being the fifth one are three of the at least two auxiliary units, and in which the regulating unit 512 and the regulating unit 516 are included in the second cluster 902. In addition the interlace unit 508 being the only one is intermediately coupled in cascade with the auxiliary unit 506 being the second one and the auxiliary unit 510 being the third one to form a H8H topology 800 in accordance with the circuit setting being the preferred as shown in FIG. 5, in which the auxiliary unit 506 being the second one is pre-coupled to the interlace unit 508 being the only one by means of the high pre side terminal D8 coupled to the high side terminal H6, the access terminal Q8 coupled to the common side terminal C6 and the low pre side terminal F8 coupled to the low side terminal L6, and in which the auxiliary unit 510 being the third one is post-coupled to the interlace unit 508 being the only one by means of the high post side terminal G8 coupled to the high side terminal H10, the interlink terminal S8 coupled to the common side terminal C10 and the low post side terminal K8 coupled to the low side terminal L10. Furthermore the interlink unit 520 is coupled in cascade with the auxiliary unit 518 being the fifth one in accordance with the circuit diagram as shown in FIG. 7 by means of the high end terminal P20 coupled to the high side terminal H18 and the low end terminal T20 coupled to the low side terminal L18. As a result the crosswise switching charge pump setting as shown in FIG. 10 is started with the first cluster and ended with the interlink unit, in which the interlace unit is alternately coupled in cascade with the auxiliary unit 506 being the second one and the auxiliary unit 510 being the third one. The high side terminal H2, the common side terminal C2 and the low side terminal L2 of the auxiliary unit 502 being the first one may form an input of the crosswise switching charge pump setting coupled to an output of a dual voltage source (not shown) in accordance with the power source component FIG. 4 BLOCK 4, in which the output of the dual voltage source may comprise a positive voltage terminal coupled to the high side terminal H2, a common voltage terminal coupled to the common side terminal C2 and a negative voltage terminal coupled to the low side terminal L2 to receive a supporting voltage UinH-UinL between the high side terminal H2 and the low side terminal L2 being split equally with respect to a reference voltage Uref presented at the common side terminal C2, and in which the interlink terminal S20 in conjunction with the common side terminal C2 may form an output of the crosswise switching charge pump setting. Subsequently according to the circuit diagram as shown in FIG. 10 the mid side adjust section FM of the regulating unit 504 comprises a resistive element coupled between the common side terminals C2 and C6. The high side adjust section FH of the regulating unit 504 comprises an inductive element coupled between the high side terminals H2 and H6, in which the at least one capacitive element coupled between the high side terminal H2 and the common side terminal C2, the at least one capacitive element coupled between the high side terminal H6 and the common side terminal C6, the inductive element coupled between the high side terminals H2 and H6 as well as the resistive element coupled between the common side terminals C2 and C6 may form a high side low pass pi-filter to yield a resulting impedance increasing with increasing frequency after a cut-off frequency of the high side low pass pi-filter between the high side terminals H2 and H6 for setting an attenuated frequency range after the cut-off frequency provided that the resistive element coupled between the common side terminals C2 and C6 may set a Q-factor for the high side low pass pi-filter. The low side adjust section FL of the regulating unit 504 comprises an inductive element coupled between the low side terminals L2 and L6, in which the at least one capacitive element coupled between the common side terminal C2 and the low side terminal L2, the at least one capacitive element coupled between the common side terminal C6 and the low side terminal L6, the inductive element coupled between the low side terminals L2 and L6 as well as the resistive element coupled between the common side terminals C2 and C6 may form a low side low pass pi-filter to yield a resulting impedance increasing with increasing frequency after a cut-off frequency of the low side low pass pi-filter between the low side terminals L2 and L6 for setting an attenuated frequency range after the cut-off frequency provided that the resistive element coupled between the common side terminals C2 and C6 may set the Q-factor for the low side low pass pi-filter. Furthermore the mid side adjust section FM of the regulating unit 512 comprises a resistive element coupled between the common side terminals C10 and C14. The high side adjust section FH of the regulating unit 512 comprises an inductive element coupled between the high side terminals H10 and H14, in which the at least one capacitive element coupled between the high side terminal H10 and the common side terminal C10, the at least one capacitive element coupled between the high side terminal H14 and the common side terminal C14, the inductive element coupled between the high side terminals H10 and H14 as well as the resistive element coupled between the common side terminals C10 and C14 may form a high side low pass pi-filter to yield a resulting impedance increasing with increasing frequency after a cut-off frequency of the high side low pass pi-filter between the high side terminals H10 and H14 for setting an attenuated frequency range after the cut-off frequency provided that the resistive element coupled between the common side terminals C10 and C14 may set a Q-factor for the high side low pass pi-filter. The low side adjust section FL of the regulating unit 512 comprises an inductive element coupled between the low side terminals L10 and L14, in which the at least one capacitive element coupled between the common side terminal C10 and the low side terminal L10, the at least one capacitive element coupled between the common side terminal C14 and the low side terminal L14, the inductive element coupled between the low side terminals L10 and L14 as well as the resistive element coupled between the common side terminals C10 and C14 may form a low side low pass pi-filter to yield a resulting impedance increasing with increasing frequency after a cut-off frequency of the low side low pass pi-filter between the low side terminals L10 and L14 for setting an attenuated frequency range after the cut-off frequency provided that the resistive element coupled between the common side terminals C10 and C14 may set the Q-factor for the low side low pass pi-filter. Subsequently the interlace unit 508 being the only one is intermediately coupled in cascade with the first cluster 900 and the second cluster 902, in which the first cluster is pre-coupled and the second cluster is post-coupled to the interlace unit 508 being the only one, and in which the second cluster is post-coupled to the interlink unit 520. Consequently the first cluster 900 and the second cluster 902 each comprising the high side low pass pi-filter and the low side low pass pi-filter may provide the means for highly improved characteristic switching properties in a high frequency (HF) range of the interlace unit 508 being the only one as well as the interlink unit 520, in which the high side low pass pi-filter as well as the low side low pass pi-filter may exhibit a cut-off frequency of for example 20 kHz in conjunction with the Q-factor of ½. Needless to say that the inductive element included in the respective high side low pass pi-filters as well as included in the respective low side low pass pi-filters may comprise a resistive element due to internal losses, a resistive element coupled in series, a resistive element coupled in parallel or a combination thereof to provide the Q-factor as set, in which the inductive element may be for example a ferrite bead set for high loss in a high frequency range, and in which the resistive element coupled between the common side terminals C2 and C6 as well as the resistive element coupled between the common side terminals C10 and C14 may be omitted by means of a connection between the common side terminals C2 and C6 as well as a connection between the common side terminals C10 and C14.

In accordance with the further aspect of the present invention a crosswise switching charge pump setting implemented with at least two auxiliary units and at least one interlace unit may comprise the parallel coupling of two or more of the at least two auxiliary units to form a cluster. The cluster of the parallel coupling of two or more of the at least two auxiliary units may further comprise various well-known filter configurations in the art such as for example a symmetric differential low pass filter, a resonant filter, a common mode filter or a combination thereof, in which the symmetric differential low pass filter may be of a first order, a second order or a higher order in conjunction with under-damped, critical damped or over-damped filter characteristics such as the high side low pass pi-filter and the low side low pass pi-filter configured symmetrical for the first cluster as well as for the second cluster as shown in FIG. 10 each exhibiting a RLC filter of the second order being for example critical damped.

According to the further aspect of the present invention a cluster comprising the parallel coupling of two or more of the at least two auxiliary units may further comprise the voltage regulator means interposed between two auxiliary units included in the parallel coupling of the cluster, in which the voltage regulator means may comprise a linear regulator setting, a switched-mode power supply (SMPS) setting or a combination thereof operable to regulate, to restore, to adapt or a combination thereof, and in which the voltage regulator means may be operable of sourcing as well as sinking electrical charge per unit of time. Subsequently the voltage regulator means may be subdivided in high side voltage regulator means and low side voltage regulator means, in which the two auxiliary units included in the parallel coupling of the cluster may comprise a coupling between the high side terminals interposed by the high side voltage regulator means, a coupling between the low side terminals interposed by the low side voltage regulator means as well as a coupling of the common side terminals, a reference terminal of the high side voltage regulator means and a reference terminal of the low side voltage regulator means to set a high side voltage being adjusted between the high side terminal and the common side terminal of one of the two auxiliary units coupled to an output of the high side voltage regulator means as well as to set a low side voltage being adjusted between the common side terminal and the low side terminal of the one of the two auxiliary units coupled to an output of the low side voltage regulator means. As an example the voltage regulator means subdivided in the high side voltage regulator means and the low side voltage regulator means may be operable to regulate for providing low noise characteristics of the high side voltage being adjusted and the low side voltage being adjusted, the voltage regulator means subdivided in high side voltage regulator means and low side voltage regulator means may be operable to restore due to voltage loss the high side voltage being adjusted plus the low side voltage being adjusted equal to a supporting voltage presented at an input of a crosswise switching charge pump setting. Furthermore the voltage regulator means subdivided in high side voltage regulator means and low side voltage regulator means may be operable to adapt the high side voltage being adjusted plus the low side voltage being adjusted exhibiting a voltage being weighted as determined for a bit being significant, in which the high side voltage being adjusted plus the low side voltage being adjusted exhibiting the voltage being weighted may be provided at the respective terminals of the auxiliary being pre-coupled to the interlace unit of each of N H8H topologies configured for a crosswise switching charge pump setting, N being larger than or equal to two. Subsequently the voltage being weighted may be one of N voltages being weighted and a bit being significant may be one of N bits being significant, in which the N voltages may form a set arranged from a lowest voltage to a highest voltage associated with a set of the N bits arranged from a bit being least significant (LSB) to a bit being most significant (MSB).

According to the circuit diagram as shown in FIG. 10 the mid side adjust section FM of the regulating unit 516 may comprise a connection between the common side terminals C14 and C18. The high side adjust section FH of the regulating unit 516 may comprise the high side voltage regulator means coupled between the high side terminals H14 and H18, in which the high side voltage regulator means comprising the input coupled to the high side terminal H14, the reference terminal coupled to the common side terminal C18 and the output coupled to the high side terminal H18 may form in conjunction with the at least one capacitive element coupled between the high side terminal H14 and the common side terminal C14 as well as the at least one capacitive element coupled between the high side terminal H18 and the common side terminal C18 a high side voltage regulator for providing the high side voltage being adjusted between the high side terminal H18 and the common side terminal C18 of the auxiliary unit 518 coupled to the output of the high side voltage regulator. The low side adjust section FL of the regulating unit 516 may comprise the low side voltage regulator means coupled between the low side terminals L14 and L18, in which the low side voltage regulator means comprising the input coupled to the low side terminal L14, the reference terminal coupled to the common side terminal C18 and the output coupled to the low side terminal L18 may form in conjunction with the at least one capacitive element coupled between the common side terminal C14 and the low side terminal L14 as well as the at least one capacitive element coupled between the common side terminal C18 and the low side terminal L18 a low side voltage regulator for providing the low side voltage being adjusted between the common side terminal C18 and the low side terminal L18 of the auxiliary unit 518 coupled to the output of the low side voltage regulator.

According to the circuit diagram as shown in FIG. 10 it is to be noted that a combination of the high side low pass pi-filter and the high side voltage regulator as well as a combination of the low side low pass pi-filter and the low side voltage regulator as configured for the second cluster 902 may result in an attenuated frequency range of for example DC up to or above 30 MHz at the high side terminal H18 with respect to high side terminal H10 as well as at the low side terminal L18 with respect to low side terminal L10, in which the attenuated frequency range may be extended up to or above 1 GHz by means of additional low pass filter means. Furthermore it is to be noted that the mid side adjust section FM of a regulating unit may comprise a resistive element such as the resistive element coupled between the common side terminals C10 and C14, in which a resistive element included in the mid side adjust section FM of a regulating unit, a resistive element between the common side terminal C6 and the access terminal Q8, a resistive element between the interlink terminal S8 and the common side terminal C10 or a combination thereof may provide for example snubber means, current monitoring means, inrush current limiter means or a combination thereof.

In general according to the further aspect of the present invention it is to be noted that a cluster comprising the parallel coupling of two or more of the at least two auxiliary units may further comprise protection means such as a Fuse, a Thermistor for example a negative temperature coefficient (NTC) thermistor, a Varistor exhibiting a voltage-dependent resistor (VDR) and the like. In addition it is to be noted that the cluster may include one or more regulating units for the functions specified provided that a regulating unit being one of the one or more regulating units is interposed between two auxiliary units included in the parallel coupling of the cluster, in which a regulating unit comprising voltage regulator means may be alternately implemented with a regulating unit comprising low pass filter means.

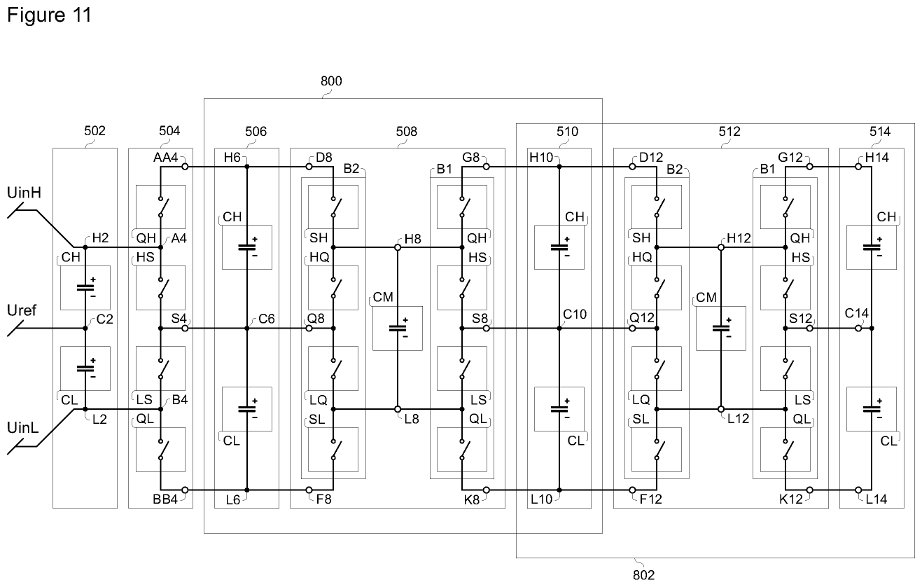

In accordance with the present invention the charge pump component as shown in FIG. 4 BLOCK 5 responsive to at least one pulse modulated control signal emanated from the control component as shown in FIG. 4 BLOCK 2, the receiving component as shown in FIG. 4 BLOCK 1 or a combination thereof includes a crosswise switching charge pump setting implemented with at least two auxiliary units and at least one interlace unit, in which in accordance with a circuit diagram as shown in FIG. 11 the crosswise switching charge pump setting comprises three auxiliary units being three of the at least two auxiliary units and two interlace units being two of the at least one interlace unit, and in which the charge pump component further includes an extended auxiliary unit and an extended switching unit coupled in cascade. According to the circuit diagram as shown in FIG. 11 each of the at least one interlace unit 508 and 512 is implemented with the second circuit setting being the alternative as shown in FIG. 6 and supplemented with a common side capacitance section CM, in which the common side capacitance section may comprise all technical features specified for the high side capacitance section and the low side capacitance section in accordance with the present invention. Subsequently a capacitive element being one of at least one capacitive element included in the common side capacitance section CM may be coupled between the common high side terminal H8, H12 and the common low side terminal L8, L12 of each of the at least one interlace unit 800 and 802 to stabilise the common high side terminal and the common low side terminal with respect to one another during a switched transition as will be well understood by those skilled in the art. According to the circuit diagram as shown in FIG. 11 the crosswise switching charge pump setting may be constituted by means of each of the at least one interlace unit alternately coupled in cascade with an auxiliary unit being one of the at least two auxiliary units, in which each of the at least one interlace unit is intermediately coupled in cascade with an auxiliary unit being pre-coupled and an auxiliary unit being post-coupled to form two H8H topologies 800 and 802 overlapping one another, and in which the crosswise switching charge pump setting may be started with an auxiliary unit 506 being a first one of the at least two auxiliary units and may be ended with an auxiliary unit 514 being a third one of the at least two auxiliary units. An interlace unit 508 being a first one of the at least one interlace unit is intermediately coupled in cascade with the auxiliary unit 506 being the first one and an auxiliary unit 510 being a second one of the at least two auxiliary units to form a first H8H topology 800, in which the auxiliary unit 506 being the first one is pre-coupled to the interlace unit 508 being the first one by means of the high pre side terminal D8 coupled to the high side terminal H6, the access terminal Q8 coupled to the common side terminal C6 and the low pre side terminal F8 coupled to the low side terminal L6, and in which the auxiliary unit 510 being the second one is post-coupled to the interlace unit 508 being the first one by means of the high post side terminal G8 coupled to the high side terminal H10, the interlink terminal S8 coupled to the common side terminal C10 and the low post side terminal K8 coupled to the low side terminal L10. An interlace unit 512 being a second one of the at least one interlace unit is intermediately coupled in cascade with the auxiliary unit 510 being the second one and an auxiliary unit 514 being a third one of the at least two auxiliary units to form a second H8H topology 802, in which the auxiliary unit 510 being the second one is pre-coupled to the interlace unit 512 being the second one by means of the high pre side terminal D12 coupled to the high side terminal H10, the access terminal Q12 coupled to the common side terminal C10 and the low pre side terminal F12 coupled to the low side terminal L10, and in which the auxiliary unit 514 being the third one is post-coupled to the interlace unit 512 being the second one by means of the high post side terminal G12 coupled to the high side terminal H14, the interlink terminal S12 coupled to the common side terminal C14 and the low post side terminal K12 coupled to the low side terminal L14. According to the circuit diagram as shown in FIG. 11 the charge pump component comprises the extended auxiliary unit 502 and the extended switching unit 504 coupled in cascade to implement a switching charge pump setting in conjunction with the auxiliary unit 506 being the first one, in which the extended auxiliary unit 502 may comprise all technical features specified for an auxiliary unit being one of at least two auxiliary unit included in a crosswise switching charge pump setting in accordance with the present invention, and in which the extended switching unit 504 may comprise all technical features specified for the first circuit branch B1 of the second circuit setting being the alternative as shown in FIG. 6. Subsequently the extended switching unit 504 is intermediately coupled in cascade with the extended auxiliary unit 502 and the auxiliary unit 506 being the first one, in which the extended auxiliary unit 502 is pre-coupled to the extended switching unit 504 by means of a high side terminal H2 coupled to a common high side terminal A4 and a low side terminal L2 coupled to a common low side terminal B4, and in which the auxiliary unit 506 being the first one is post-coupled to the extended switching unit 504 by means of the high side terminal H6 coupled to a high end terminal AA4, the common side terminal C6 coupled to an interlink terminal S4 and the low side terminal L6 coupled to a low end terminal BB4. In addition the high side terminal H2, the common side terminal C2 and the low side terminal L2 of the extended auxiliary unit 502 may form an input of the charge pump component coupled to an output of a dual voltage source (not shown), in which the output of the dual voltage source may comprise a positive voltage terminal coupled to the high side terminal H2, a common voltage terminal coupled to the common side terminal C2 and a negative voltage terminal coupled to the low side terminal L2 to receive a supporting voltage UinH-UinL between the high side terminal H2 and the low side terminal L2 being split equally with respect to a reference voltage Uref presented at the common side terminal C2, and in which the interlink terminal S12 of the interlace unit 512 being the second one in conjunction with the common side terminal C2 may form an output of the charge pump component. According to the switching charge pump setting configured of the extended switching unit 504 intermediately coupled in cascade with the extended auxiliary unit 502 and the auxiliary unit being the first one 506 the extended switching unit may be implemented with a circuit setting as shown in FIG. 11 operable to couple in response to one or more of the at least one pulse modulated control signal the extended auxiliary unit with the auxiliary unit being the first one repetitively in accordance with a high operational state and a low operational state of the extended switching unit, in which during the high operational state the interlink terminal S4 as well as the common side terminal C6 may be coupled with the high side terminal H2 and the low side terminal L6 may be coupled with the low side terminal L2 by means of the at least one mid high side switching element HS as well as the at least one low side switching element QL of the extended switching unit 504 being conductive and the at least one high side switching element QH as well as the at least one mid low side switching element LS of the extended switching unit 504 being non-conductive to generate a positive switched voltage provided at the interlink terminal S4 with respect to the reference voltage Uref presented at the common side terminal C2 equal to a high side voltage presented between the high side terminal H2 and the common side terminal C2, to charge at least one capacitive element of the low side capacitance section CL coupled between the common side terminal C6 and the low side terminal L6 up to a voltage level equal to the supporting voltage provided at the input and to generate a summated positive switched voltage provided at the high side terminal H6 with respect to the reference voltage presented at the common side terminal C2 equal to the high side voltage presented between the high side terminal H6 and the common side terminal C6 summated with the high side voltage presented between the high side terminal H2 and the common side terminal C2, and in which during the low operational state the interlink terminal S4 as well as the common side terminal C6 may be coupled with the low side terminal L2 and the high side terminal H6 may be coupled with the high side terminal H2 by means of the at least one high side switching element QH as well as the at least one mid low side switching element LS of the extended switching unit 504 being conductive and the at least one mid high side switching element HS as well as the at least one low side switching element QL of the extended switching unit 504 being non-conductive to generate a negative switched voltage provided at the interlink terminal S4 with respect to the reference voltage Uref presented at the common side terminal C2 equal to a low side voltage presented between the common side terminal C2 and the low side terminal L2, to charge at least one capacitive element of the high side capacitance section CH coupled between the high side terminal H6 and the common side terminal C6 up to a voltage level equal to the supporting voltage provided at the input and to generate a summated negative switched voltage provided at the low side terminal L6 with respect to the reference voltage presented at the common side terminal C2 equal to the low side voltage presented between the common side terminal C6 and the low side terminal L6 summated with the low side voltage presented between the common side terminal C2 and the low side terminal L2. Consequently by means of the high operational state and the low operational state repeated successively during each switching period of the extended switching unit 504 associated with an operational switching frequency both the at least one capacitive element of the high side capacitance section CH and the at least one capacitive element of the low side capacitance section CL of the auxiliary unit 506 being the first one may be charged alternately by means of the extended auxiliary unit 502, by means of the dual voltage source or a combination thereof, in which a voltage presented between the high side terminal H6 and the low side terminal L6 of the auxiliary unit 506 being the first one may be equal to the supporting voltage being doubled.

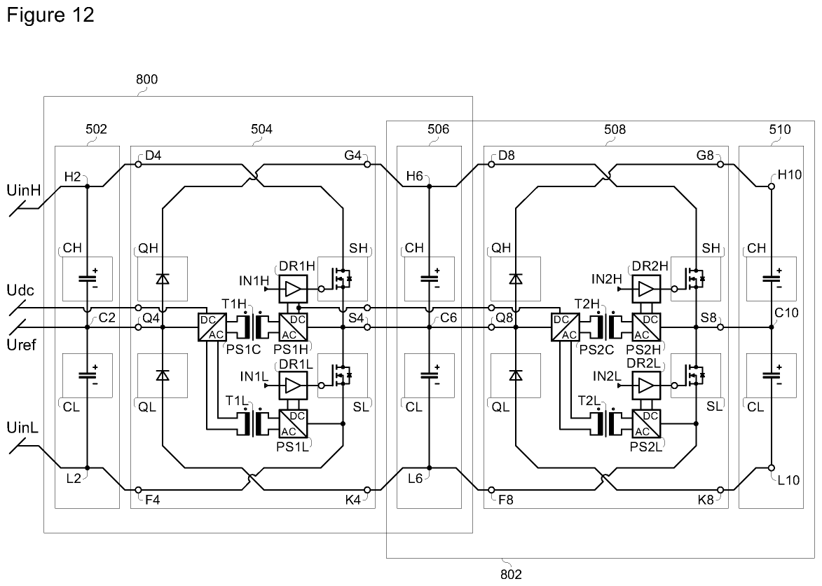

In accordance with the present invention the charge pump component as shown in FIG. 4 BLOCK 5 responsive to at least one pulse modulated control signal emanated from the control component as shown in FIG. 4 BLOCK 2, the receiving component as shown in FIG. 4 BLOCK 1 or a combination thereof includes a crosswise switching charge pump setting implemented with at least two auxiliary units and at least one interlace unit, in which in accordance with a circuit diagram as shown in FIG. 12 the crosswise switching charge pump setting comprises three auxiliary units being three of the at least two auxiliary units and two interlace units being two of the at least one interlace unit, and in which each of the at least one interlace unit may comprise gate drive means as well as galvanic isolated power supply means for powering the gate drive means. According to the circuit diagram as shown in FIG. 12 each of the at least one interlace unit 508 and 512 is implemented with the first circuit setting being the preferred as shown in FIG. 5B. According to the circuit diagram as shown in FIG. 12 the crosswise switching charge pump setting may be constituted by means of each of the at least one interlace unit alternately coupled in cascade with an auxiliary unit being one of the at least two auxiliary units, in which each of the at least one interlace unit is intermediately coupled in cascade with an auxiliary unit being pre-coupled and an auxiliary unit being post-coupled to form two H8H topologies 800 and 802 overlapping one another, and in which the crosswise switching charge pump setting may be started with an auxiliary unit 502 being a first one of the at least two auxiliary units and may be ended with an auxiliary unit 510 being a third one of the at least two auxiliary units. An interlace unit 504 being a first one of the at least one interlace unit is intermediately coupled in cascade with the auxiliary unit 502 being the first one and an auxiliary unit 506 being a second one of the at least two auxiliary units to form a first H8H topology 800, in which the auxiliary unit 502 being the first one is pre-coupled to the interlace unit 504 being the first one by means of the high pre side terminal D4 coupled to the high side terminal H2, the access terminal Q4 coupled to the common side terminal C2 and the low pre side terminal F4 coupled to the low side terminal L2, and in which the auxiliary unit 506 being the second one is post-coupled to the interlace unit 504 being the first one by means of the high post side terminal G4 coupled to the high side terminal H6, the interlink terminal S4 coupled to the common side terminal C6 and the low post side terminal K4 coupled to the low side terminal L6. An interlace unit 508 being a second one of the at least one interlace unit is intermediately coupled in cascade with the auxiliary unit 506 being the second one and an auxiliary unit 510 being a third one of the at least two auxiliary units to form a second H8H topology 802, in which the auxiliary unit 506 being the second one is pre-coupled to the interlace unit 508 being the second one by means of the high pre side terminal D8 coupled to the high side terminal H6, the access terminal Q8 coupled to the common side terminal C6 and the low pre side terminal F8 coupled to the low side terminal L6, and in which the auxiliary unit 510 being the third one is post-coupled to the interlace unit 508 being the second one by means of the high post side terminal G8 coupled to the high side terminal H10, the interlink terminal S8 coupled to the common side terminal C10 and the low post side terminal K8 coupled to the low side terminal L10. In addition the high side terminal H2, the common side terminal C2 and the low side terminal L2 of the auxiliary unit 502 being the first one may form an input of the crosswise switching charge pump setting coupled to an output of a dual voltage source (not shown), in which the output of the dual voltage source may comprise a positive voltage terminal coupled to the high side terminal H2, a common voltage terminal coupled to the common side terminal C2 and a negative voltage terminal coupled to the low side terminal L2 to receive a supporting voltage UinH-UinL between the high side terminal H2 and the low side terminal L2 being split equally with respect to a reference voltage Uref presented at the common side terminal C2, and in which an input of a centre power supply PS1C included in the galvanic isolated power supply means of the interlace unit 504 being the first one may be coupled to an output of an accessory power supply (not shown) to receive a DC voltage presented at Udc with respect to the reference voltage Uref as shown in FIG. 12. The interlink terminal S8 of the interlace unit 508 being the second one in conjunction with the common side terminal C2 may form an output of the crosswise switching charge pump setting. According to the circuit diagram as shown in FIG. 12, the galvanic isolated power supply means of each interlace unit 504, 508 implemented with a switched-mode power supply (SMPS) setting in conjunction with linear voltage regulator means may comprise a centre power supply PS1C, PS2C, a high side power supply PS1H, PS2H and a low side power supply PS1L, PS2L, in which the galvanic isolated power supply means may further comprise a high side pulse transformer T1H, T2H intermediately coupled in cascade with the centre power supply PS1C, PS2C and the high side power supply PS1H, PS2H as well as a low side pulse transformer T1L, T2L intermediately coupled in cascade with the centre power supply PS1C, PS2C and the low side power supply PS1L, PS2L to provide the means for galvanic isolation and for setting a voltage ratio between a primary winding and a secondary winding of the high side pulse transformer T1H, T2H as well as the low side pulse transformer T1L, T2L, and in which a coupling between an output of the high side power supply PS1H of the interlace unit 504 being the first one and an input of the centre power supply PS2C of the interlace unit 508 being the second one to transfer power from the galvanic isolated power supply means included in the interlace unit 504 being the first one to the galvanic isolated power supply means included in the interlace unit 508 being the second one may be interposed by low pass filter means, protection means or a combination thereof. Subsequently a DC voltage presented at the input of the centre power supply PS1C, PS2C may be converted into a pulse modulated AC voltage exhibiting for example an operational switching frequency between 250 kHz and 1.5 MHz to drive the primary winding of the high side pulse transformer T1H, T2H at an output of the centre power supply PS1C, PS2C as well as to drive the primary winding of the low side pulse transformer T1L, T2L at the output of the centre power supply, in which the pulse modulated AC voltage being magnetically coupled from the primary winding to the secondary winding of the high side pulse transformer T1H, T2H may be provided at an input of the high side power supply PS1H, PS2H to convert the pulse modulated AC voltage into a positive DC voltage, a negative DC voltage and a reference voltage for the positive and negative DC voltage presented at an output of the high side power supply PS1H, PS2H, and in which the pulse modulated AC voltage being magnetically coupled from the primary winding to the secondary winding of the low side pulse transformer T1L, T2L may be provided at an input of the low side power supply PS1H, PS2H to convert the pulse modulated AC voltage into a positive DC voltage, a negative DC voltage and a reference voltage for the positive and negative DC voltage presented at an output of the low side power supply PS1L, PS2L. Consequently the output of the high side power supply PS1H, PS2H powered by means of the centre power supply PS1C, PS2C may be coupled to an input of a high side control driving circuit CD1H, CD2H and the output of the low side power supply PS1L, PS2L powered by means of the centre power supply PS1C, PS2C may be coupled to the input a low side control driving circuit CD1L, CD2L, in which an output of the high side control driving circuit CD1H, CD2H may be coupled to a gate terminal of a MOSFET SH to drive the MOSFET SH in response to a pulse modulated control signal IN1H, IN2H being one of the at least one pulse modulated control signal, and in which an output of the low side control driving circuit CD1L, CD2L may be coupled to a gate terminal of a MOSFET SL to drive the MOSFET SL in response to a pulse modulated control signal IN1L, IN2L being one of the at least one pulse modulated control signal.

It is to be noted, that an interwinding capacitance resided between the primary winding and the secondary winding of the high side pulse transformer T1H, T2H due to capacitive coupling and thereby the interwinding capacitance resided between the access terminal Q4, Q8 and the interlink terminal S4, S8 of each of the at least one interlace unit 504, 508 may be a part of an accumulated capacitance whereas the interwinding capacitance resided between the primary winding and the secondary winding of the low side pulse transformer T1L, T2L and thereby the interwinding capacitance resided between the access terminal Q4, Q8 and the low pre side terminal F4, F8 of each of the at least one interlace unit 504, 508 may be excluded as being a part of the accumulated capacitance, in which the accumulated capacitance resided between the access terminal Q4, Q8 and the interlink terminal S4, S8 of an interlace unit being one of the at least one interlace unit 504, 508 may be a summation of for example (output) capacitances resided in the constituted semiconductors being passively and actively driven, the interwinding capacitance of the high side pulse transformer T1H, T2H and capacitance due to capacitive coupling in general between parts of the crosswise switching charge pump setting. In accordance with the objective of the present invention to obtain the switching power converter system capable of generating a high resolution well-balanced high voltage pulse-width-modulated (PWM) signal switched at a high operational switching frequency in conjunction with fast balanced transition times the accumulated capacitance of the interlace unit 504 being the first one and the accumulated capacitance of the interlace unit 508 being the second one may be coupled in series during either the high operational state or the low operational state to obtain an overall accumulated capacitance presented between the interlink terminal of the interlace unit 508 being the second one and the common side terminal C2 of the auxiliary unit 502 being the first one, in which the overall accumulated capacitance may be equal to the accumulated capacitance of one of the at least one interlace unit 504, 508 reduced by a factor equal to the number of interlace units 504, 508 being all of the at least one interlace unit provided that the interlace units are substantial identical configured. Furthermore taken advantage of an interlace unit being one of the at least one interlace unit 504, 508 comprising the accumulated capacitance resided between the interlink terminal and the access terminal the accumulated capacitance may vary along a rising edge during a switched voltage transition in an equal manner as the varying of the accumulated capacitance along a falling edge during a switched voltage transition, in which the accumulated capacitance may vary during a switched voltage transition due to for example a varying (output) capacitance across a given voltage range resided in each of the constituted semiconductors being passively and actively driven. Subsequently the accumulated capacitance optimised to a minimum value for each of the at least one interlace unit 504, 508 in conjunction with the accumulated capacitances of each of the at least one interlace unit 504, 508 coupled in series during either the high operational state or the low operational may result in a method to obtain the overall accumulated capacitance resided between the interlink terminal S8 and the common side terminal C2 of the output, in which the overall accumulated capacitance being well-balanced with respect to the common side terminal C2 may provide the means for an equal time duration of a rising voltage transition edge and a falling voltage transition edge presented at the interlink terminal S8 with respect to the common side terminal C2. Consequently the objective of the present invention may be achieved in accordance with the crosswise switching charge pump setting comprising the overall accumulated capacitance as described above allowing the means for the crosswise switching charge pump setting to operate at a high voltage level in conjunction with a high operational switching frequency as well as fast well-balanced switched transition times and to provide a very energy efficient concept.

Needless to say that reducing and balancing parasitic inductance elements as well as resistive elements in general may be an objective as well in particular in a high current domain in order to reduce for example a transient voltage during a switched voltage transition as well as conduction losses. In addition the accumulated capacitance and adjacent parasitic inductances (not shown) may be resided in an interlace unit 504, 508 being one of the at least one interlace unit to form a resonant circuit comprising a resonant frequency, in which the resonant frequency may be mitigated by means of for example a R/C snubber, a R/L snubber or a combination thereof. Needless to say that the R/C snubber is in particular suitable in a high current domain whereas the R/L snubber is in particular suitable in a high voltage domain.

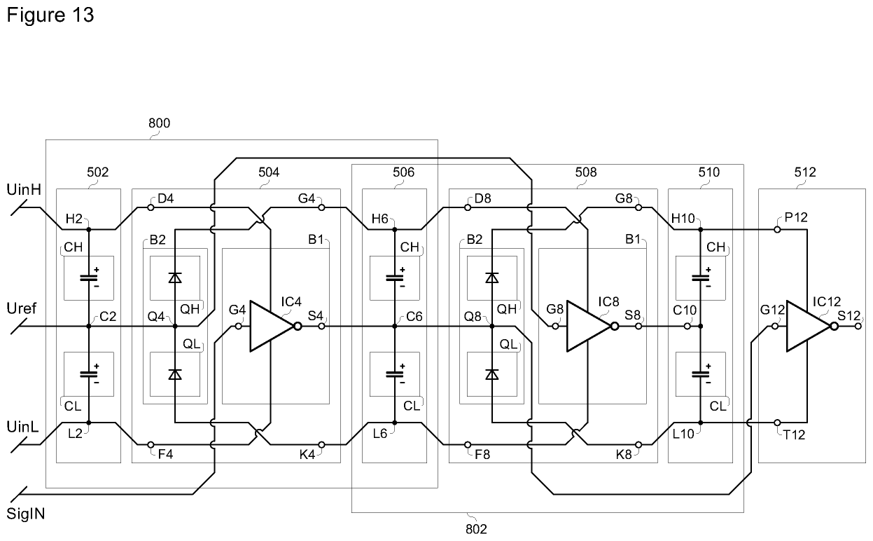

In accordance with the present invention the charge pump component as shown in FIG. 4 BLOCK 5 responsive to at least one pulse modulated control signal emanated from the control component as shown in FIG. 4 BLOCK 2, the receiving component as shown in FIG. 4 BLOCK 1 or a combination thereof includes a crosswise switching charge pump setting implemented with at least two auxiliary units and at least one interlace unit, in which in accordance with a circuit diagram as shown in FIG. 13 the crosswise switching charge pump setting comprises three auxiliary units being three of the at least two auxiliary units, two interlace units being two of the at least one interlace unit and an interlink unit. According to the circuit diagram as shown in FIG. 13 each of the at least one interlace unit 504, 508 is implemented with the first circuit setting being the preferred, in which the first circuit branch B1 of the first circuit setting is constituted with an integrated circuit IC4, IC8 comprising the at least one high side switching element and the at least one low side switching element rather than the first circuit branch B1 of the first circuit setting constituted with a discrete circuit as shown in FIG. 5B, and in which the second circuit branch B2 is constituted with a discrete circuit as shown in FIG. 5B. In addition the interlink unit 512 may be constituted with an integrated circuit IC12 as well comprising the at least one high side switching element and the at least one low side switching element in accordance with the circuit diagram as shown in FIG. 7, in which the integrated circuit IC12 of the interlink unit as well as the integrated circuit IC4, IC8 of the first circuit branch B1 of the first circuit setting may be implemented with for example an inverting LVC logic gate or an integrated switching power module each responsive to a pulse modulated control signal. According to the circuit diagram as shown in FIG. 13 the crosswise switching charge pump setting may be constituted by means of each of the at least one interlace unit alternately coupled in cascade with an auxiliary unit being one of the at least two auxiliary units, in which each of the at least one interlace unit is intermediately coupled in cascade with an auxiliary unit being pre-coupled and an auxiliary unit being post-coupled to form two H8H topologies 800, 802 overlapping one another, and in which the crosswise switching charge pump setting may be started with an auxiliary unit 502 being a first one of the at least two auxiliary units and may be ended with the interlink unit 512. An interlace unit 504 being a first one of the at least one interlace unit is intermediately coupled in cascade with the auxiliary unit 502 being the first one and an auxiliary unit 506 being a second one of the at least two auxiliary units to form a first H8H topology 800, in which the auxiliary unit 502 being the first one is pre-coupled to the interlace unit 504 being the first one by means of the high pre side terminal D4 coupled to the high side terminal H2, the access terminal Q4 coupled to the common side terminal C2 and the low pre side terminal F4 coupled to the low side terminal L2, and in which the auxiliary unit 506 being the second one is post-coupled to the interlace unit 504 being the first one by means of the high post side terminal G4 coupled to the high side terminal H6, the interlink terminal S4 coupled to the common side terminal C6 and the low post side terminal K4 coupled to the low side terminal L6. An interlace unit 508 being a second one of the at least one interlace unit is intermediately coupled in cascade with the auxiliary unit 506 being the second one and an auxiliary unit 510 being a third one of the at least two auxiliary units to form a second H8H topology 802, in which the auxiliary unit 506 being the second one is pre-coupled to the interlace unit 508 being the second one by means of the high pre side terminal D8 coupled to the high side terminal H6, the access terminal Q8 coupled to the common side terminal C6 and the low pre side terminal F8 coupled to the low side terminal L6, and in which the auxiliary unit 510 being the third one is post-coupled to the interlace unit 508 being the second one by means of the high post side terminal G8 coupled to the high side terminal H10, the interlink terminal S8 coupled to the common side terminal C10 and the low post side terminal K8 coupled to the low side terminal L10. The interlink unit 512 is coupled in cascade with the auxiliary unit 510 being the third one in accordance with the circuit diagram as shown in FIG. 7 by means of the high end terminal P12 coupled to the high side terminal H10 and the low end terminal T12 coupled to the low side terminal L10. In addition the high side terminal H2, the common side terminal C2 and the low side terminal L2 of the auxiliary unit 502 being the first one may form an input of the crosswise switching charge pump setting coupled to an output of a dual voltage source (not shown), in which the output of the dual voltage source may comprise a positive voltage terminal coupled to the high side terminal H2, a common voltage terminal coupled to the common side terminal C2 and a negative voltage terminal coupled to the low side terminal L2 to receive a supporting voltage UinH-UinL between the high side terminal H2 and the low side terminal L2 being split equally with respect to a reference voltage Uref presented at the common side terminal C2. An input terminal G4 of the integrated circuit being a first one IC4 in conjunction with for example the low side terminal L2 or the common side terminal C2 may form a signal input to receive a pulse modulated control signal SigIN being the at least one pulse modulated control signal emanated from the control component, the receiving component or a combination thereof, in which an input terminal G8 of the integrated circuit being a second one IC8 may be coupled to the common side terminal C2 and an input terminal G12 of the integrated circuit being a third one IC12 may be coupled to the common side terminal C6. The interlink terminal S12 of the interlink unit 512 in conjunction with the common side terminal C2 may form an output of the crosswise switching charge pump setting.

According to the circuit diagram as shown in FIG. 13 the crosswise switching charge pump setting may be responsive to the pulse modulated control signal being the at least one pulse modulated control signal SigIN provided at the signal input, in which the integrated circuit being the first one IC4 may generate in response to the at least one pulse modulated control signal SigIN the positive switched voltage during the high operational state and the negative switched voltage during the low operational state between the interlink terminal S4 and the common side terminal C2 to obtain a pulse modulated control signal for the integrated circuit being a second one IC8 provided at an input terminal G8 with respect to the interlink terminal S4. Subsequently the integrated circuit being the second one IC8 may generate in response to the pulse modulated control signal emanated from the integrated circuit being the first one IC4 the positive switched voltage during the high operational state and the negative switched voltage during the low operational state between the interlink terminal S8 and the common side terminal C6 to obtain a pulse modulated control signal for the integrated circuit being a third one IC12 provided at an input terminal G12 with respect to the interlink terminal S8. Consequently according to the circuit diagram as shown in FIG. 13 the crosswise switching charge pump setting may be characterised as a ripple through converter asynchronously controlled, in which the first H8H topology 800 may initialise a ripple cascaded successively from one H8H topology 800 to the next one 802 or from one H8H topology 802 to the next interlink unit 512 with an interval determined by a delay time of an integrated circuit being one of the respective integrated circuits IC4, IC8, IC12. It is to be emphasised that the pulse modulated control signal being the at least one pulse modulated control signal SigIN provided at the signal input may be emanated directly from the receiving component as shown in FIG. 4 BLOCK 1, from the control component as shown in FIG. 4 BLOCK 2 or a combination thereof, in which the link component as shown in FIG. 4 BLOCK 3 may be omitted in whole or in part. Needless to say that the control component as shown in FIG. 4 BLOCK 2, the receiving component as shown in FIG. 4 BLOCK 1 or a combination thereof may provide two or more of the at least one pulse modulated control signal generated asynchronously, synchronously or a combination thereof for the charge pump component as shown in FIG. 4 BLOCK 5.

It is to be emphasised in accordance with the present invention that a crosswise switching charge pump setting comprising at least two auxiliary units and at least one interlace unit may be implemented in a modular form having for example connector means as well as cooling means, in which for example an auxiliary unit being one of the at least two auxiliary units, a cluster comprising the parallel coupling of two or more of the at least two auxiliary units, an interlace unit being one of the at least one interlace unit, an interlink unit or a combination thereof may be detachably provided. In addition the crosswise switching charge pump setting may be implemented in a discreet setting of parts, an integrated setting of parts or a combination thereof, in which an interlace unit being one of the at least one interlace unit as well as an interlink unit may be implemented in whole or in part with a monolithic semiconductor die setting, and in which a setting of parts of an interlink unit and the first circuit branch B1 of an interlace unit being one of the at least one interlace unit may be substantial identical. Furthermore it is to be noted that an interlink unit may be substantial identical to an interlace unit being one of the at least one interlace unit, in which the interlace unit comprising all technical features of the interlink unit may be configured to operate as an interlink unit.

Needless to say that in accordance with the present invention a crosswise switching charge pump setting comprising at least two auxiliary units and at least one interlace unit may be supplemented with various parts to best utilise the present invention in various embodiments and with various modifications as are suited to the particular use contemplated, in which for example a capacitive element may be coupled between the high side terminal and the low side terminal of an auxiliary unit being one of the at least two auxiliary units as well as between the high pre side terminal and the low pre side terminal of an interlace unit being one of the at least one interlace unit.

It is to be emphasised that the methods, circuits and parts exhibited in the present invention with reference to the enclosed exemplary embodiments are presented for purpose of illustration and description only, in which the precise forms disclosed are not intended to be exhaustive or to be limited. In addition the present invention for the functions specified may be implemented with hardware means in conjunction with software means, in which both the hardware means as well as software means may interrelate with one another. Subsequently it will be apparent to those skilled in the art that the spirit and scope of the present invention resides not only in any novel feature taken alone, but rather in the particular combination of all of its structures as well as all of its relationships for the functions specified.

The described embodiments were chosen in order to best explain the principles of the present invention and its practical application to thereby enable others being skilled in the art to best utilise the present invention in various embodiments and with various modifications as are suited to the particular use contemplated.

It is intended that the scope of the present invention may be defined by the claims appended hereto.

1-22. (canceled)

23. A charge pump setting for use in a switching power converter system, the charge pump setting comprising
at least two auxiliary units, an auxiliary unit of the at least two auxiliary units having a high side capacitance section (CH) and a low side capacitance section (CL) coupled in series, the high side capacitive section and the low side capacitance section having each at least one capacitive element, and a high side voltage being a voltage across the high side capacitance section and a low side voltage being a voltage across the low side capacitance section;
at least one interlace unit, an interlace unit of the at least one interlace unit having a first circuit branch (B1) and a second circuit branch (B2), the first circuit branch and the second circuit branch having each a plurality of switching elements coupled in series, and the interlace unit operable to generate a high operational state and a low operational state during a switching period; and
a configuration of an auxiliary unit being pre-coupled (502) to an interlace unit (504) and an auxiliary unit being post-coupled (506) to the interlace unit (504) to form a topology of switching elements intermediately coupled in cascade with capacitive elements, wherein,
the low side capacitance section (CL) of the auxiliary unit being pre-coupled (502) is coupled in parallel with the high side capacitance section (CH) of the auxiliary unit being post-coupled (506) during the low operational state of the interlace unit (504) for transferring an electrical charge,
the high side capacitance section (CH) of the auxiliary unit being pre-coupled (502) is coupled in parallel with the low side capacitance section (CL) of the auxiliary unit being post-coupled (506) during the high operational state of the interlace unit (504) for transferring an electrical charge,
the low side capacitance section (CL) of the auxiliary unit being pre-coupled (502) is coupled in series with the low side capacitance section (CL) of the auxiliary unit being post-coupled (506) during the low operational state of the interlace unit (504) for generating a summated voltage, and
the high side capacitance section (CH) of the auxiliary unit being pre-coupled (502) is coupled in series with the high side capacitance section (CH) of the auxiliary unit being post-coupled (506) during the high operational state of the interlace unit (504) for generating a summated voltage,
such that irrespective of a ratio between the high side voltage and the low side voltage of the auxiliary unit being pre-coupled (502) and the ratio between the low side voltage and the high side voltage of the auxiliary unit being post-coupled (506) the summated voltage of the low side voltage of the auxiliary unit being pre-coupled (502) and the low side voltage of the auxiliary unit being post-coupled (506) during the low operational state of the interlace unit (504) is equal in absolute values to the summated voltage of the high side voltage of the auxiliary unit being pre-coupled (502) and the high side voltage of the auxiliary unit being post-coupled (506) during the high operational state of the interlace unit (504).

24. A charge pump setting according to claim 23, wherein an interlace unit is responsive to at least one pulse modulated control signal emanated from a receiving component, from a control component, or from a combination thereof for generating the high operational state and the low operational state repetitively associated with an operational switching frequency.

25. A charge pump setting according to claim 23, wherein a capacitive element of the at least one capacitive element is a capacitor or a battery, the capacitive element coupled between a high side terminal and a common side terminal of the high capacitance section of an auxiliary unit, or the capacitive element coupled between the common side terminal and a low side terminal of the low capacitive section of an auxiliary unit.

26. A charge pump setting according to claim 23, wherein an interlace unit is alternately coupled in cascade with an auxiliary unit or a cluster comprising a parallel coupling of two or more of the at least two auxiliary units to form one or more topologies configured for the charge pump setting, an auxiliary unit having the high side capacitance section coupled between a high side terminal and a common side terminal and having the low side capacitance section coupled between the common side terminal and a low side terminal, and the cluster implemented by means of the high side terminals coupled, the common side terminals coupled and the low side terminals coupled of the two or more of the at least two auxiliary units, wherein the high side terminal, the common side terminal as well as the low side terminal of an auxiliary unit or a combination of the respective terminals of the auxiliary unit may form an input, an output or a part thereof.

27. A charge pump setting according to claim 26, wherein the cluster comprising the parallel coupling of two or more of the at least two auxiliary units may further comprise low pass filter means, resonant filter means, voltage regulator means, protection means, inrush current limiter means, current monitoring means or a combination thereof.

28. A charge pump setting according to claim 26, wherein the first circuit branch and the second circuit branch of an interlace unit comprise each the plurality of switching elements being at least one high side switching element and at least one low side switching element coupled in series, the at least one high side switching element of the second circuit branch coupled between a high post side terminal and an access terminal, the at least one low side switching element of the second circuit branch coupled between the access terminal and a low post side terminal, the at least one high side switching element of the first circuit branch coupled between a high pre side terminal and an interlink terminal, and the at least one low side switching element of the first circuit branch coupled between the interlink terminal and a low pre side terminal, an auxiliary unit being pre-coupled and an auxiliary unit being post-coupled to the interlace unit by means of the high post side terminal coupled to the high side terminal of the auxiliary unit being post-coupled, the access terminal coupled to the common side terminal of the auxiliary unit being pre-coupled, the low post side terminal coupled to the low side terminal of the auxiliary unit being post-coupled, the high pre side terminal coupled to the high side terminal of the auxiliary unit being pre-coupled, the interlink terminal coupled to the common side terminal of the auxiliary unit being post-coupled, and the low pre side terminal coupled to low side terminal of the auxiliary unit being pre-coupled, wherein the access terminal as well as the interlink terminal may form an input, an output or a part thereof.

29. A charge pump setting according to claim 28, wherein during the high operational state of the interlace unit the at least one high side switching element of the first circuit branch as well as the at least one low side switching element of the second circuit branch is conductive and the at least one low side switching element of the first circuit branch as well as the at least one high side switching element of the second circuit branch is non-conductive, and wherein during the low operational state of the interlace unit the at least one low side switching element of the first circuit branch as well as the at least one high side switching element of the second circuit branch is conductive and the at least one high side switching element of the first circuit branch as well as the at least one low side switching element of the second circuit branch is non-conductive.

30. A charge pump setting according to claim 28, wherein the at least one high side switching element and the at least one low side switching element of both the first circuit branch and the second circuit branch are constituted with actively driven semiconductors, an actively driven semiconductor of the actively driven semiconductors responsive to a pulse modulated control signal, or wherein the at least one high side switching element and the at least one low side switching element of the first circuit branch are constituted with actively driven semiconductors, an actively driven semiconductor of the actively driven semiconductors responsive to a pulse modulated control signal, and the at least one high side switching element and the at least one low side switching element of the second circuit branch are constituted with passively driven semiconductors.

31. A charge pump setting according to claim 26, wherein the first circuit branch and the second circuit branch of an interlace unit comprise each the plurality of switching elements being at least one high side switching element, at least one mid high side switching element, at least one mid low side switching element and at least one low side switching element coupled in series in this order, the at least one high side switching element of the second circuit branch coupled between a high pre side terminal and a common high side terminal, the at least one mid high side switching element of the second circuit branch coupled between the common high side terminal and an access terminal, the at least one mid low side switching element of the second circuit branch coupled between the access terminal and a common low side terminal, the at least one low side switching element of the second circuit branch coupled between the common low side terminal and a low pre side terminal, the at least one high side switching element of the first circuit branch coupled between a high post side terminal and the common high side terminal, the at least one mid high side switching element of the first circuit branch coupled between the common high side terminal and an interlink terminal, the at least one mid low side switching element of the first circuit branch coupled between the interlink terminal and the common low side terminal of the interlace unit, the at least one low side switching element of the first circuit branch coupled between the common low side terminal and a low post side terminal of the interlace unit, an auxiliary unit being pre-coupled and an auxiliary unit being post-coupled to the interlace unit by means of the high post side terminal coupled to the high side terminal of the auxiliary unit being post-coupled, the access terminal coupled to the common side terminal of the auxiliary unit being pre-coupled, the low post side terminal coupled to the low side terminal of the auxiliary unit being post-coupled, the high pre side terminal coupled to the high side terminal of the auxiliary unit being pre-coupled, the interlink terminal coupled to the common side terminal of the auxiliary unit being post-coupled, and the low pre side terminal coupled to low side terminal of the auxiliary unit being pre-coupled, wherein the access terminal as well as the interlink terminal may form an input, an output or a part thereof.

32. A charge pump setting according to claim 31, wherein during the high operational state of the interlace unit the at least one high side switching element of the second circuit branch, the at least one mid low side switching element of the second circuit branch, the at least one mid high side switching element of the first circuit branch as well as the at least one low side switching element of the first circuit branch is conductive and the at least one mid high side switching element of the second circuit branch, the at least one low side switching element of the second circuit branch, the at least one high side switching element of the first circuit branch as well as the at least one mid low side switching element of the first circuit branch is non-conductive, and wherein during the low operational state of the interlace unit the at least one mid high side switching element of the second circuit branch, the at least one low side switching element of the second circuit branch, the at least one high side switching element of the first circuit branch as well as the at least one mid low side switching element of the first circuit branch is conductive and the at least one high side switching element of the second circuit branch, the at least one mid low side switching element of the second circuit branch, the at least one mid high side switching element of the first circuit branch as well as the at least one low side switching element of the first circuit branch is non-conductive.

33. A charge pump setting according to claim 31, wherein the at least one high side switching element, the at least one mid high side switching element, the at least one mid low side switching element and the at least one low side switching element of both the first circuit branch and the second circuit branch are constituted with actively driven semiconductors, an actively driven semiconductor of the actively driven semiconductors responsive to a pulse modulated control signal, or wherein the at least one high side switching element and the at least one low side switching element of the second circuit branch as well as the at least one mid high side switching element and the at least one mid low side switching element of the first circuit branch are constituted with actively driven semiconductors, an actively driven semiconductor of the actively driven semiconductors responsive to a pulse modulated control signal, and the at least one mid high side switching element and the at least one mid low side switching element of the second circuit branch as well as the at least one high side switching element and the at least one low side switching element of the first circuit branch are constituted with passively driven semiconductors.

34. A charge pump setting according to claim 26, wherein an interlink unit is coupled in cascade with an auxiliary unit, the interlink unit having a circuit branch, the circuit branch comprising at least one high side switching element and at least one low side switching element coupled in series, the at least one high side switching element coupled between a high end terminal and an interlink terminal, the at least one low side switching element coupled between the interlink terminal and a low end terminal, the high end terminal coupled to the high side terminal of the auxiliary unit, and the low end terminal coupled to the low side terminal of the auxiliary unit, wherein the interlink terminal of the interlink unit forms an input, an output or a part thereof of the charge pump setting.

35. A charge pump setting according to claim 34, wherein the interlink unit is operable to generate a high operational state and a low operational state during a switching period associated with an operational switching frequency, during the high operational state of the interlink unit the at least one high side switching element being conductive and the at least one low side switching element being non-conductive, and during the low operational state of the interlink unit the at least one low side switching element being conductive and the at least one high side switching element being non-conductive.

36. A charge pump setting according to claim 34, wherein the at least one high side switching element and the at least one low side switching element of the circuit branch are constituted with actively driven semiconductors, an actively driven semiconductor of the actively driven semiconductors responsive to a pulse modulated control signal.

37. A system having a switching power converter, wherein the switching power converter comprises all technical features of the charge pump setting according to claim 23.

38. A system having a switching power converter, wherein the switching power converter comprises all technical features of the charge pump setting according to claim 25.

39. A system having a switching power converter, wherein the switching power converter comprises all technical features of the charge pump setting according to claim 26.

40. A system having a switching power converter, wherein the switching power converter comprises all technical features of the charge pump setting according to claim 28.

41. A system having a switching power converter, wherein the switching power converter comprises all technical features of the charge pump setting according to claim 31.

42. A system having a switching power converter, wherein the switching power converter comprises all technical features of the charge pump setting according to claim 34.
